(19) United States
(12) Patent Application Publication
(10) Pub. No.: US 2025/0349782 A1
(43) Pub. Date: Nov. 13, 2025

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun Jee, Suwon-si (KR)

(73) Assignee: SAMSUNG ELECTRONICS CO., LTD., Suwon-si (KR)

(21) Appl. No.: 19/027,378

(22) Filed: Jan. 17, 2025

(30) Foreign Application Priority Data
May 8, 2024 (KR) 10-2024-0060760

(51) Int. Cl. H01L 23/00; H01L 23/31; H01L 23/49; H01L 25/11

(52) U.S. Cl. CPC H01L 24/24; H01L 23/3135; H01L 23/49; H01L 24/32; H01L 24/73; H01L 25/117; H01L 2224/24146; H01L 2224/244; H01L 2224/32225; H01L 2224/73267; H01L 2225/06562

(57) ABSTRACT

Provided is a semiconductor package including a redistribution structure, a first chip structure on the redistribution structure and including a first lower semiconductor chip, a second lower semiconductor chip on the first lower semiconductor chip, and a first lower molding layer, a second lower molding layer on the first chip structure, a plurality of conductive posts penetrating the second lower molding layer, and a second chip structure on the first chip structure and the plurality of conductive posts and including a first upper semiconductor chip, a first upper chip post extending from the first upper semiconductor chip, a second upper semiconductor chip on the first upper semiconductor chip, a second upper chip post extending from the second upper semiconductor chip, and an upper molding layer, wherein a width of the first upper chip post is less than a width of the plurality of conductive posts in a horizontal direction.

### CROSS-REFERENCE TO RELATED APPLICATION

This application claims priority to Korean Patent Application No. 10-2024-0060760, filed on May 8, 2024, in the Korean Intellectual Property Office, the disclosure of which is incorporated by reference herein in its entirety.

### BACKGROUND

### 1. Field

Embodiments of the present disclosure relate to a semiconductor package, and more particularly, to a semiconductor package including an offset-stacked semiconductor chip.

### 2. Description of Related Art

Recently, with the rapid development of the electronics industry and needs of users, electronic devices have become more compact, multi-functional, and large in capacity, and thus, highly integrated semiconductor chips are required. Accordingly, semiconductor packages that include highly integrated semiconductor chips with an increased number of connection terminals for input/output (I/O) and have guaranteed connection reliability have been designed.

### SUMMARY

One or more embodiments provide a semiconductor package in which an offset-stacked semiconductor chip is connected to a redistribution structure through a conductive post.

In addition, the objectives of one or more embodiments are not limited to those mentioned above, and other objectives will be clearly understood by those skilled in the art from the following descriptions.

According to an aspect of one or more embodiments, there is provided a semiconductor package including a redistribution structure, a first chip structure on the redistribution structure and including a first lower semiconductor chip, a second lower semiconductor chip on the first lower semiconductor chip in a vertical direction and shifted with respect to the first lower semiconductor chip in a horizontal direction, and a first lower molding layer on the first lower semiconductor chip and the second lower semiconductor chip, a second lower molding layer on the redistribution structure and side surfaces of the first chip structure, a plurality of conductive posts spaced apart from the first chip structure, on the redistribution structure, penetrating the second lower molding layer, a plurality of conductive posts including a first conductive post and a second conductive post, and a second chip structure on the first chip structure, the second lower molding layer, and the plurality of conductive posts, the second chip structure including a first upper semiconductor chip, a first upper chip post extending from the first upper semiconductor chip to the first conductive post, a second upper semiconductor chip on the first upper semiconductor chip in the vertical direction and shifted with respect to the first upper semiconductor chip in the horizontal direction, a second upper chip post extending from the second upper semiconductor chip to the second conductive post, and an upper molding layer on the first upper semiconductor chip, the first upper chip post, the second upper semiconductor chip, and the second upper chip post, wherein a width of the first upper chip post included in the second chip structure is less than a width of the first conductive post in the horizontal direction, wherein a width of the second upper chip post included in the second chip structure is less than a width of the second conductive post in the horizontal direction, and wherein a side surface of the upper molding layer included in the second chip structure is coplanar with a side surface of the second lower molding layer.

According to another aspect of one or more embodiments, there is provided a semiconductor package including a redistribution structure, a first chip structure on the redistribution structure and including a first lower semiconductor chip, a second lower semiconductor chip on the first lower semiconductor chip in a vertical direction and shifted with respect to the first lower semiconductor chip in a horizontal direction, and a first lower molding layer on the first lower semiconductor chip and the second lower semiconductor chip, a second lower molding layer on the redistribution structure and side surfaces of the first chip structure, an intermediate insulating layer on the first chip structure and the second lower molding layer, a plurality of conductive posts spaced apart from the first chip structure, on the redistribution structure, penetrating the second lower molding layer and the intermediate insulating layer, the plurality of conductive posts including a first conductive post and a second conductive post, and a second chip structure on the intermediate insulating layer and the plurality of conductive posts, the second chip structure including a first upper semiconductor chip, a first upper chip post extending from the first upper semiconductor chip to the first conductive post, a second upper semiconductor chip on the first upper semiconductor chip in the vertical direction and shifted with respect to the first upper semiconductor chip in the horizontal direction, a second upper chip post extending from the second upper semiconductor chip to the second conductive post, and an upper molding layer on the first upper semiconductor chip, the first upper chip post, the second upper semiconductor chip, and the second upper chip post, wherein a width of the first upper chip post of the second chip structure is less than a width of the first conductive post in a horizontal direction, wherein a width of the second upper chip post of the second chip structure is less than a width of the second conductive post in the horizontal direction, and wherein a side surface of the upper molding layer of the second chip structure, a side surface of the second lower molding layer, and a side surface of the intermediate insulating layer are coplanar with each other.

According to still another aspect of one or more embodiments, there is provided a semiconductor package including a redistribution structure including a redistribution pattern and a redistribution insulating layer on the redistribution pattern, a first chip structure on the redistribution structure and including a first lower semiconductor chip, a first lower chip post extending downward from the first lower semiconductor chip to the redistribution structure, a second lower semiconductor chip on the first lower semiconductor chip in a vertical direction and shifted with respect to the first lower semiconductor chip in a horizontal direction, a second lower chip post extending downward from the second lower semiconductor chip to the redistribution structure, and a first lower molding layer on the first lower semiconductor chip, the first lower chip post, the second lower semiconductor chip, and the second lower chip post, a bonding layer on an upper surface of the first chip structure, a second lower molding layer on the redistribution structure, side surfaces of the first chip structure, and side surfaces of the bonding layer, a plurality of conductive posts spaced apart from the first chip structure in a horizontal direction, on the redistribution structure, and penetrating the second lower molding layer, the plurality of conductive posts including a first conductive post and a second conductive post, and a second chip structure on the first chip structure, the second lower molding layer, and the plurality of conductive posts and including a first upper semiconductor chip, a first upper chip post extending from the first upper semiconductor chip to the first conductive post, a second upper semiconductor chip on the first upper semiconductor chip in the vertical direction and shifted with respect to the first upper semiconductor chip in the horizontal direction, a second upper chip post extending from the second upper semiconductor chip to the second conductive post, and an upper molding layer on the first upper semiconductor chip, the first upper chip post, the second upper semiconductor chip, and the second upper chip post, wherein an interface is between the first lower molding layer of the first chip structure and the second lower molding layer, wherein a width of each post among the plurality of conductive posts is greater than a width of the first lower chip post, a width of the second lower chip post, a width of the first upper chip post, and a width of the second upper chip post in the horizontal direction, and wherein a side surface of the upper molding layer of the second chip structure is coplanar with a side surface of the second lower molding layer.

### BRIEF DESCRIPTION OF DRAWINGS

Embodiments will be more clearly understood from the following detailed description taken in conjunction with the accompanying drawings in which:

FIG. 1 is a schematic cross-sectional view of a semiconductor package according to one or more embodiments;

FIG. 2 is a schematic cross-sectional view of a semiconductor package according to one or more embodiments;

FIG. 3 is a schematic cross-sectional view of a semiconductor package according to one or more embodiments;

FIG. 4 is a schematic cross-sectional view of a semiconductor package according to one or more embodiments;

FIG. 5 is a schematic cross-sectional view of a semiconductor package according to one or more embodiments;

FIGS. 6A, 6B, 6C, 6D, 6E, 6F, 6g, 6H, 6I, 6J, 6K, 6L, and 6M are cross-sectional views illustrating, according to a process sequence, a method of manufacturing a semiconductor package, according to one or more embodiments; and

FIGS. 7A, 7B, 7C, 7D, 7E, 7F, 7G, 7H, and 7I are cross-sectional views illustrating, according to a process sequence, a method of manufacturing a semiconductor package, according to one or more embodiments.

### DETAILED DESCRIPTION

Embodiments set forth herein may have various modifications and various forms, and thus, one or more embodiments will be illustrated in the drawings and described in detail. However, this is not intended to limit the embodiments to specific disclosure forms.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

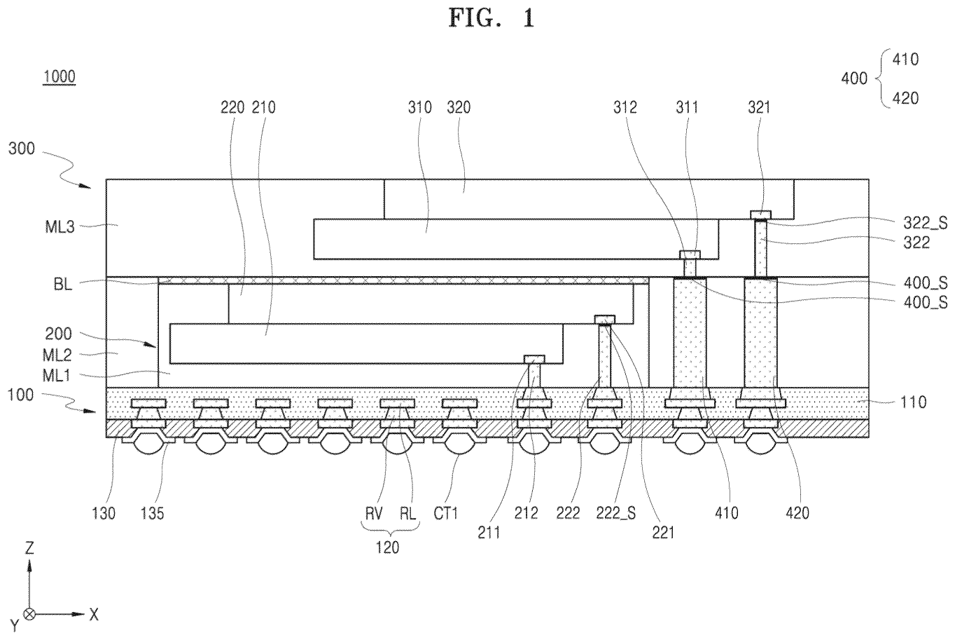

FIG. 1 is a schematic cross-sectional view of a semiconductor package 1000 according to one or more embodiments.

The semiconductor package 1000 may include a redistribution structure 100, a first chip structure 200, a second lower molding layer ML2, a plurality of conductive posts 400, and a second chip structure 300.

Hereinafter, unless particularly defined otherwise, a direction parallel to an upper surface of the redistribution structure 100 is defined as a first horizontal direction (X direction), a direction perpendicular to the upper surface of the redistribution structure 100 is defined as a vertical direction (Z direction), and a direction perpendicular to the first horizontal direction (X direction) and the vertical direction (Z direction) is defined as a second horizontal direction (Y direction). A direction combining the first horizontal direction (X direction) and the second horizontal direction (Y direction) is defined as a horizontal direction.

The redistribution structure 100 of the semiconductor package 1000 may be electrically connected to the first chip structure 200, a first upper semiconductor chip 310, and a second upper semiconductor chip 320 and may expand an input/output (I/O) pad of each of the first chip structure 200, the first upper semiconductor chip 310, and the second upper semiconductor chip 320 to an outer region of each of the first chip structure 200, the first upper semiconductor chip 310, and the second upper semiconductor chip 320.

The redistribution structure 100 may include redistribution patterns 120 including redistribution vias RV and redistribution lines RL, and a redistribution insulating layer 110 surrounding the redistribution patterns 120.

Each of the redistribution patterns 120 may include a redistribution line RL extending in the horizontal direction and a redistribution via RV extending from the redistribution line RL in the vertical direction (Z direction). Each of the redistribution lines RL may be located on at least one of upper and lower surfaces of the redistribution insulating layer 110 or inside the redistribution insulating layer 110. Each of the redistribution vias RV may penetrate the redistribution insulating layer 110 and be connected to at least portions of the redistribution lines RL.

Each of the redistribution vias RV may be completely filled with a conductive material or may have a form in which a conductive material is provided along walls of the via. Each of the redistribution patterns 120 may include a conductive material, for example, copper (Cu), aluminum (Al), silver (Ag), tin (Sn), gold (Au), nickel (Ni), lead (Pb), titanium (Ti), or an alloy thereof. The numbers and arrangements of redistribution vias RV and redistribution lines RL are not limited to those shown in the drawings and may be variously changed in embodiments.

The redistribution insulating layer 110 may include an insulating material, for example, photo-imageable dielectric (PID) resin. In this case, the redistribution insulating layer 110 may further include an inorganic filler. In one or more embodiments, the redistribution insulating layer 110 may have a multi-layer structure in which the redistribution patterns 120 are located on each layer.

In one or more embodiments, the semiconductor package 1000 may further include a passivation layer 130. The passivation layer 130 may be located on a lower surface of the redistribution structure 100 and may protect the redistribution structure 100. The passivation layer 130 may include an insulating material, for example, thermosetting resin or thermoplastic resin, but is not limited thereto.

For example, at least portions of the redistribution lines RL may be exposed through openings of the passivation layer 130. The exposed portions of the redistribution lines RL may be electrically connected to lower metal layers 135 located inside the openings.

External connection terminals CT1 may be attached to the lower metal layers 135. The external connection terminals CT1 may connect the semiconductor package 1000 to a main board of a separate electronic device on which the semiconductor package 1000 is mounted. Each of the external connection terminals CT1 may include a conductive material, for example, at least one of solder, Sn, Ag, Cu, and Al. The shape of each of the external connection terminals CT1 may be changed into various shapes, such as a land shape, a ball shape, a pillar shape, and a pin shape, in addition to a bump shape.

The first chip structure 200 may be located on the redistribution structure 100. The first chip structure 200 may include a first lower semiconductor chip 210, a second lower semiconductor chip 220, and a first lower molding layer ML1. The second lower semiconductor chip 220 may be offset-stacked on the first lower semiconductor chip 210. For example, side surfaces of the second lower semiconductor chip 220 may be offset from side surfaces of the first lower semiconductor chip 210 in the horizontal direction. The first lower molding layer ML1 may surround exposed surfaces of the first lower semiconductor chip 210 and the second lower semiconductor chip 220.

In one or more embodiments, the first lower molding layer ML1 may include, for example, epoxy resin or polyimide resin. The first lower molding layer ML1 may include, for example, an epoxy molding compound (EMC).

The first lower semiconductor chip 210 and the second lower semiconductor chip 220 may be electrically connected to the redistribution structure 100. Each of the first lower semiconductor chip 210 and the second lower semiconductor chip 220 may include an active surface (lower surface) and an inactive surface (upper surface) facing the active surface. In one or more embodiments, each of the first lower semiconductor chip 210 and the second lower semiconductor chip 220 may be located above the redistribution structure 100 such that the active surface of each of the first lower semiconductor chip 210 and the second lower semiconductor chip 220 faces the redistribution structure 100. For example, each of the first lower semiconductor chip 210 and the second lower semiconductor chip 220 may be located above the redistribution structure 100 in a face-down manner.

In one or more embodiments, a plurality of individual devices of various types may be located on the active surface of each of the first lower semiconductor chip 210 and the second lower semiconductor chip 220. The plurality of individual devices of each of the first lower semiconductor chip 210 and the second lower semiconductor chip 220 may be electrically connected to a wiring region of each of the first lower semiconductor chip 210 and the second lower semiconductor chip 220.

For example, the plurality of individual devices may include various micro-electronic devices, for example, a complementary metal-oxide-semiconductor (CMOS) transistor, a metal-oxide-semiconductor field-effect transistor (MOSFET), system large-scale integration (LSI), an image sensor such as a CMOS imaging sensor (CIS), a micro-electro-mechanical system (MEMS), an active device, and a passive device, but embodiments are not limited thereto.

In one or more embodiments, the first chip structure 200 may further include a first lower chip post 212 and a second lower chip post 222. Each of the first lower chip post 212 and the second lower chip post 222 may penetrate the first lower molding layer ML1. The first lower molding layer ML1 may surround exposed surfaces of the first lower semiconductor chip 210, the first lower chip post 212, the second lower semiconductor chip 220, and the second lower chip post 222.

The first lower chip post 212 may extend in the vertical direction (Z direction) from a lower surface of the first lower semiconductor chip 210 to the upper surface of the redistribution structure 100. The second lower chip post 222 may extend in the vertical direction (Z direction) from a lower surface of the second lower semiconductor chip 220 to the upper surface of the redistribution structure 100.

For example, the first lower chip post 212 may electrically connect the first lower semiconductor chip 210 and the redistribution structure 100 to each other, and the second lower chip post 222 may electrically connect the second lower semiconductor chip 220 and the redistribution structure 100 to each other.

The second lower chip post 222 may be spaced apart from the first lower semiconductor chip 210 and the first lower chip post 212 in the horizontal direction. For example, the second lower chip post 222 may be located below a region of the lower surface of the second lower semiconductor chip 220, which does not overlap the first lower semiconductor chip 210 in the vertical direction.

The first lower chip post 212 may extend in the vertical direction (Z direction) from an I/O pad 211 of the first lower semiconductor chip 210 to the upper surface of the redistribution structure 100. The first lower chip post 212 may electrically connect the first lower semiconductor chip 210 and the redistribution structure 100 to each other. For example, the first lower chip post 212 may be in contact with one of the redistribution vias RV of the redistribution structure 100.

In one or more embodiments, the width of each of the redistribution vias RV of the redistribution structure 100 in the horizontal direction may increase downward in the vertical direction (Z direction). For example, the width of each of the redistribution vias RV of the redistribution structure 100 in the horizontal direction may increase away from the first chip structure 200. For example, the width of each of the redistribution vias RV of the redistribution structure 100 in the horizontal direction may increase toward the lower surface of the redistribution structure 100. For example, the semiconductor package 1000 may be manufactured in a chip-first manner, and thus, the first lower chip post 212 and the second lower chip post 222 may be in direct contact with the redistribution vias RV, and the width of each of the redistribution vias RV may increase away from the first chip structure 200.

The second lower chip post 222 may extend in the vertical direction (Z direction) from an I/O pad 221 of the second lower semiconductor chip 220 to the upper surface of the redistribution structure 100. The second lower chip post 222 may be located inside the first lower molding layer ML1. The second lower chip post 222 may electrically connect the second lower semiconductor chip 220 and the redistribution structure 100 to each other. For example, the second lower chip post 222 may be in contact with one of the redistribution vias RV of the redistribution structure 100.

In one or more embodiments, a lower seed layer 222_S may be located between the second lower chip post 222 and the I/O pad 221 of the second lower semiconductor chip 220. The lower seed layer 222_S may be located on an upper surface of the second lower chip post 222. For example, the second lower chip post 222 may be formed through an electrolytic plating process by using the lower seed layer 222_S.

In one or more embodiments, the first lower chip post 212 may be attached to the first lower semiconductor chip 210 through a conductive film or may be formed through an electrolytic plating process. For example, when the first lower chip post 212 is formed through an electrolytic plating process, a seed layer may be present between the first lower chip post 212 and the I/O pad 211 of the first lower semiconductor chip 210.

The first lower semiconductor chip 210 and the second lower semiconductor chip 220 may be spaced apart from the redistribution structure 100 in the vertical direction (Z direction). For example, the first lower semiconductor chip 210 may be spaced apart from the redistribution structure 100 in the vertical direction (Z direction) with the first lower molding layer ML1 therebetween. The second lower semiconductor chip 220 may be spaced apart from the redistribution structure 100 in the vertical direction (Z direction) with the first lower semiconductor chip 210 and the first lower molding layer ML1 therebetween.

For example, a distance between the lower surface of the first lower semiconductor chip 210 and the upper surface of the redistribution structure 100 may be equal to the height of the first lower chip post 212 in the vertical direction (Z direction). For example, a distance between the lower surface of the second lower semiconductor chip 220 and the upper surface of the redistribution structure 100 may be equal to the height of the second lower chip post 222 in the vertical direction (Z direction). The height of the second lower chip post 222 in the vertical direction (Z direction) may be greater than the height of the first lower chip post 212 in the vertical direction (Z direction).

In one or more embodiments, the first chip structure 200 may further include a bonding layer BL. The bonding layer BL may be located on an upper surface of the first chip structure 200. The bonding layer BL may be located between the first chip structure 200 and an upper molding layer ML3. For example, in the process of manufacturing the semiconductor package 1000, the first chip structure 200 may be attached to the upper molding layer ML3 through the bonding layer BL. In one or more embodiments, the bonding layer BL may include an adhesive film, such as a direct adhesive film (DAF).

The second lower molding layer ML2 may be located on the redistribution structure 100 and may surround side surfaces of the first chip structure 200. A side surface of the second lower molding layer ML2 may be coplanar with a side surface of the redistribution structure 100. The second lower molding layer ML2 may be in contact with side surfaces of the first lower molding layer ML1 of the first chip structure 200. For example, the second lower molding layer ML2 may surround side surfaces of the first lower molding layer ML1 of the first chip structure 200 and side surfaces of the bonding layer BL. For example, an upper surface of the second lower molding layer ML2 may be coplanar with an upper surface of the bonding layer BL.

In one or more embodiments, the second lower molding layer ML2 may include epoxy resin or polyimide resin. The second lower molding layer ML2 may include, for example, an EMC.

In one or more embodiments, an interface may be present between the first lower molding layer ML1 of the first chip structure 200 and the second lower molding layer ML2. For example, even when the first lower molding layer ML1 and the second lower molding layer ML2 include identical constituent materials, due to a difference in curing time between the first lower molding layer ML1 and the second lower molding layer ML2, an interface may be present between the first lower molding layer ML1 and the second lower molding layer ML2.

The plurality of conductive posts 400 may be spaced apart from the first chip structure 200 in the horizontal direction and may be located on the redistribution structure 100. The plurality of conductive posts 400 may extend from the upper surface of the second lower molding layer ML2 to a lower surface of the second lower molding layer ML2 and may penetrate the second lower molding layer ML2.

In one or more embodiments, the semiconductor package 1000 may further include a first seed layer 400_S. The first seed layer 400_S may be located on an upper surface of each of the plurality of conductive posts 400. For example, an upper surface of the first seed layer 400_S may be coplanar with the upper surface of the second lower molding layer ML2. Each of the plurality of conductive posts 400 may be formed through electrolytic plating by using the first seed layer 400_S.

In one or more embodiments, the height of each of the plurality of conductive posts 400 in the vertical direction (Z direction) may be greater than that of the second lower chip post 222 of the first chip structure 200. For example, in the process of manufacturing the semiconductor package 1000, the second lower chip post 222 of the first chip structure 200 and the plurality of conductive posts 400 may be formed through different process processes. Accordingly, each of plurality of conductive posts 400 and the second lower chip post 222 of the first chip structure 200 may have different heights in the vertical direction (Z direction).

In one or more embodiments, the width of each of the plurality of conductive posts 400 may be different from the width of each of the first lower chip post 212 and the width of the second lower chip post 222 of the first chip structure 200 in the horizontal direction. For example, the width of each of the plurality of conductive posts 400 may be greater than the width of each of the first lower chip post 212 and the width of the second lower chip post 222 of the first chip structure 200 in the horizontal direction.

In one or more embodiments, the plurality of conductive posts 400 may include a first conductive post 410 and a second conductive post 420. A distance between the first conductive post 410 and the first chip structure 200 may be less than a distance between the second conductive post 420 and the first chip structure 200 in the horizontal direction.

For example, the first conductive post 410 may be located below the first upper semiconductor chip 310 of the second chip structure 300 and may be electrically connected to the first upper semiconductor chip 310. The second conductive post 420 may be located below the second upper semiconductor chip 320 of the second chip structure 300 and may be electrically connected to the second upper semiconductor chip 320.

The second chip structure 300 may be located on the first chip structure 200, the second lower molding layer ML2, and the plurality of conductive posts 400. The second chip structure 300 may include the first upper semiconductor chip 310, a first upper chip post 312, the second upper semiconductor chip 320, a second upper chip post 322, and the upper molding layer ML3.

The first upper semiconductor chip 310 may be located above the second lower molding layer ML2. The second upper semiconductor chip 320 may be offset-stacked on the first upper semiconductor chip 310. For example, side surfaces of the second upper semiconductor chip 320 may be offset from side surfaces of the first upper semiconductor chip 310 in the horizontal direction. For example, the area of the second upper semiconductor chip 320, which overlaps the first chip structure 200 in the vertical direction (Z direction), may be less than the area of the first upper semiconductor chip 310, which overlaps the first chip structure 200 in the vertical direction (Z direction).

The first upper semiconductor chip 310 may overlap the first chip structure 200 and the first conductive post 410 in the vertical direction (Z direction). The second upper semiconductor chip 320 may overlap the first upper semiconductor chip 310 and the second conductive post 420 in the vertical direction (Z direction).

In one or more embodiments, each of the first upper semiconductor chip 310 and the second upper semiconductor chip 320 may include an active surface (lower surface) and an inactive surface (upper surface) facing the active surface. In one or more embodiments, each of the first upper semiconductor chip 310 and the second upper semiconductor chip 320 may be located above the second lower molding layer ML2 such that the active surface of each of the first upper semiconductor chip 310 and the second upper semiconductor chip 320 faces the redistribution structure 100. For example, each of the first upper semiconductor chip 310 and the second upper semiconductor chip 320 may be mounted above the second lower molding layer ML2 in a face-down manner.

In one or more embodiments, a plurality of individual devices of various types may be located on the active surface of each of the first upper semiconductor chip 310 and the second upper semiconductor chip 320. The plurality of individual devices of each of the first upper semiconductor chip 310 and the second upper semiconductor chip 320 may be electrically connected to a wiring region of each of the first upper semiconductor chip 310 and the second upper semiconductor chip 320.

For example, the plurality of individual devices may include various micro-electronic devices, for example, a CMOS transistor, a MOSFET, system LSI, an image sensor such as a CIS, an MEMS, an active device, and a passive device.

The first upper chip post 312 may be located below the first upper semiconductor chip 310 and may extend in the vertical direction (Z direction) from a lower surface of the first upper semiconductor chip 310 to an upper surface of the first conductive post 410. The second upper chip post 322 may be located below the second upper semiconductor chip 320 and may extend in the vertical direction (Z direction) from a lower surface of the second upper semiconductor chip 320 to an upper surface of the second conductive post 420.

The second upper chip post 322 may be spaced apart from the first upper semiconductor chip 310 and the first upper chip post 312 in the horizontal direction. For example, the second upper chip post 322 may be located below a region of the lower surface of the second upper semiconductor chip 320, which does not overlap the first upper semiconductor chip 310 in the vertical direction.

For example, the first upper chip post 312 may electrically connect the first upper semiconductor chip 310 and the first conductive post 410 to each other, and the second upper chip post 322 may electrically connect the second upper semiconductor chip 320 and the second conductive post 420 to each other. For example, the first upper chip post 312 may be in contact with an I/O pad 311 of the first upper semiconductor chip 310, and the second upper chip post 322 may be in contact with an I/O pad 321 of the second upper semiconductor chip 320.

In one or more embodiments, an upper seed layer 322_S may be located between the second upper chip post 322 and the I/O pad 321 of the second upper semiconductor chip 320. The upper seed layer 322_S may be located on an upper surface of the second upper chip post 322. For example, the second upper chip post 322 may be formed through an electrolytic plating process by using the upper seed layer 322_S.

In one or more embodiments, the first upper chip post 312 may be attached to the first upper semiconductor chip 310 through a conductive film or may be formed through an electrolytic plating process. For example, when the first upper chip post 312 is formed through an electrolytic plating process, a seed layer may be present between the first upper chip post 312 and the I/O pad 311 of the first upper semiconductor chip 310.

In one or more embodiments, the width of the first upper chip post 312 and the width of the second upper chip post 322 may each be less than the width of each of the plurality of conductive posts 400 in the horizontal direction. For example, the width of the first upper chip post 312 may be less than the width of the first conductive post 410. The width of the second upper chip post 322 may be less than the width of the second conductive post 420 in the horizontal direction. For example, a portion of the upper surface of the first seed layer 400_S, which is located on the upper surface of the first conductive post 410, may be in contact with the first upper chip post 312, and the remaining portion of the upper surface of the first seed layer 400_S may be in contact with the upper molding layer ML3.

The upper molding layer ML3 may be located on the second lower molding layer ML2 and the first chip structure 200 and may surround exposed surfaces of the first upper semiconductor chip 310, the first upper chip post 312, the second upper semiconductor chip 320, and the second upper chip post 322.

The upper molding layer ML3 may be located below the first upper semiconductor chip 310 and the second upper semiconductor chip 320. The first upper semiconductor chip 310 may be spaced apart from the first chip structure 200 and the second lower molding layer ML2 in the vertical direction (Z direction) with the upper molding layer ML3 therebetween. The second upper semiconductor chip 320 may be spaced apart from the first chip structure 200 and the second lower molding layer ML2 in the vertical direction (Z direction) with the upper molding layer ML3 and the first upper semiconductor chip 310 therebetween.

The lower surface of the first upper semiconductor chip 310 and the lower surface of the second upper semiconductor chip 320 may be spaced apart from a lower surface of the upper molding layer ML3. An upper surface of the upper molding layer ML3 may be coplanar with an upper surface of the second upper semiconductor chip 320. The upper surface of the second upper semiconductor chip 320 may be exposed to the outside of the semiconductor package 1000.

In one or more embodiments, the width of the upper molding layer ML3 may be greater than the width of the first chip structure 200 in the horizontal direction. The area of the upper surface of the upper molding layer ML3 may be greater than the area of the upper surface of the first chip structure 200. The area of the upper surface of the upper molding layer ML3 may be equal to the area of the upper surface of the redistribution structure 100. For example, a side surface of the upper molding layer ML3 may be coplanar with an outer surface of the second lower molding layer ML2.

In one or more embodiments, the upper surface of the upper molding layer ML3 may be coplanar with the upper surface of the second upper semiconductor chip 320. For example, the upper surface of the second upper semiconductor chip 320 may be exposed to the outside of the semiconductor package 1000.

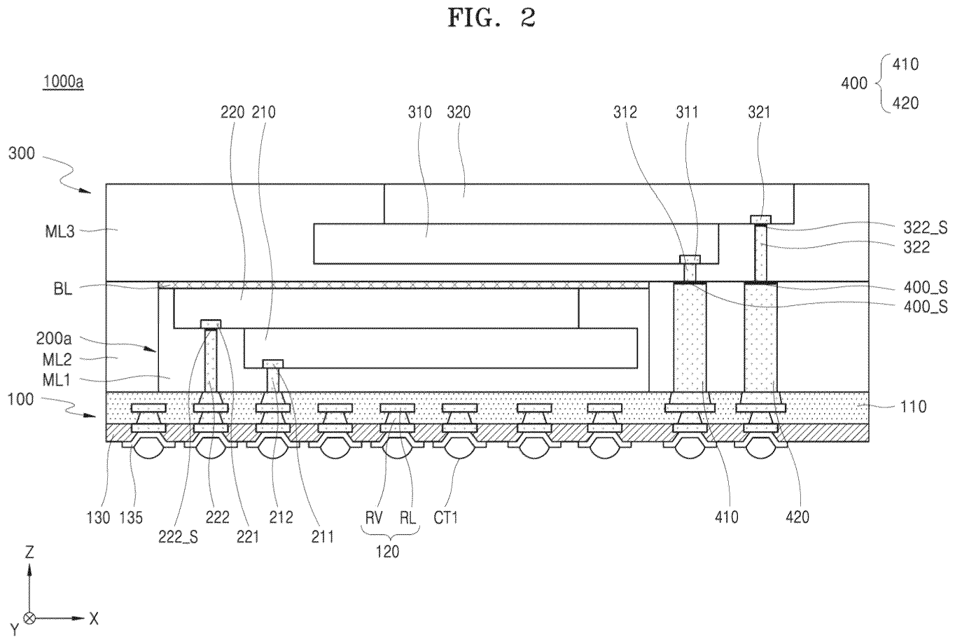

FIG. 2 is a schematic cross-sectional view of a semiconductor package 1000a according to one or more embodiments.

Most of components constituting the semiconductor package 1000a described below and materials constituting the components are substantially identical or similar to those described above with reference to FIG. 1. Accordingly, for convenience of description, differences between the semiconductor package 1000a of FIG. 2 and the semiconductor package 1000 of FIG. 1 described above will be mainly described.

Referring to FIG. 2, the semiconductor package 1000a may include a redistribution structure 100, a first chip structure 200a, a second lower molding layer ML2, a plurality of conductive posts 400, a first upper semiconductor chip 310, a first upper chip post 312, a second upper semiconductor chip 320, a second upper chip post 322, and an upper molding layer ML3.

The first chip structure 200a may include a first lower semiconductor chip 210 and a second lower semiconductor chip 220 offset-stacked on the first lower semiconductor chip 210. For example, side surfaces of the second lower semiconductor chip 220 may be offset from side surfaces of the first lower semiconductor chip 210 in the horizontal direction. For example, the second lower semiconductor chip 220 may be stacked on the first lower semiconductor chip 210 such that an I/O pad 221 located on a lower surface of the second lower semiconductor chip 220 is located outside and exposed from the first lower semiconductor chip 210. A direction in which the second lower semiconductor chip 220 is offset on the first lower semiconductor chip 210 may be referred to as a first direction.

The first upper semiconductor chip 310 may be located above the first chip structure 200a and the second lower molding layer ML2. For example, a portion of the first upper semiconductor chip 310 may overlap the first chip structure 200a in the vertical direction (Z direction), and the remaining portion of the first upper semiconductor chip 310 may overlap the second lower molding layer ML2 in the vertical direction (Z direction). For example, an I/O pad 311 of the first upper semiconductor chip 310, which is located on a lower surface of the first upper semiconductor chip 310, may be located above the second lower molding layer ML2.

The second upper semiconductor chip 320 may be offset-stacked on the first upper semiconductor chip 310. For example, side surfaces of the second upper semiconductor chip 320 may be offset from side surfaces of the first upper semiconductor chip 310 in the horizontal direction. The second upper semiconductor chip 320 may be stacked on the first upper semiconductor chip 310 such that an I/O pad 321 of the second upper semiconductor chip 320, which is located on a lower surface of the second upper semiconductor chip 320, is located outside and exposed from the first upper semiconductor chip 310. For example, a direction in which the second upper semiconductor chip 320 is offset on the first upper semiconductor chip 310 may be referred to as a second direction.

For example, the I/O pad 311 of the first upper semiconductor chip 310 may be located outside and exposed from the first chip structure 200a, and the I/O pad 321 of the second upper semiconductor chip 320 may be located outside and exposed from the first upper semiconductor chip 310 and the first chip structure 200a.

In one or more embodiments, the first direction and the second direction may be different from each other. For example, the first direction and the second direction may be opposite directions. For example, the direction in which the second lower semiconductor chip 220 is offset on the first lower semiconductor chip 210 and the direction in which the second upper semiconductor chip 320 is offset on the first upper semiconductor chip 310 may be independent of each other.

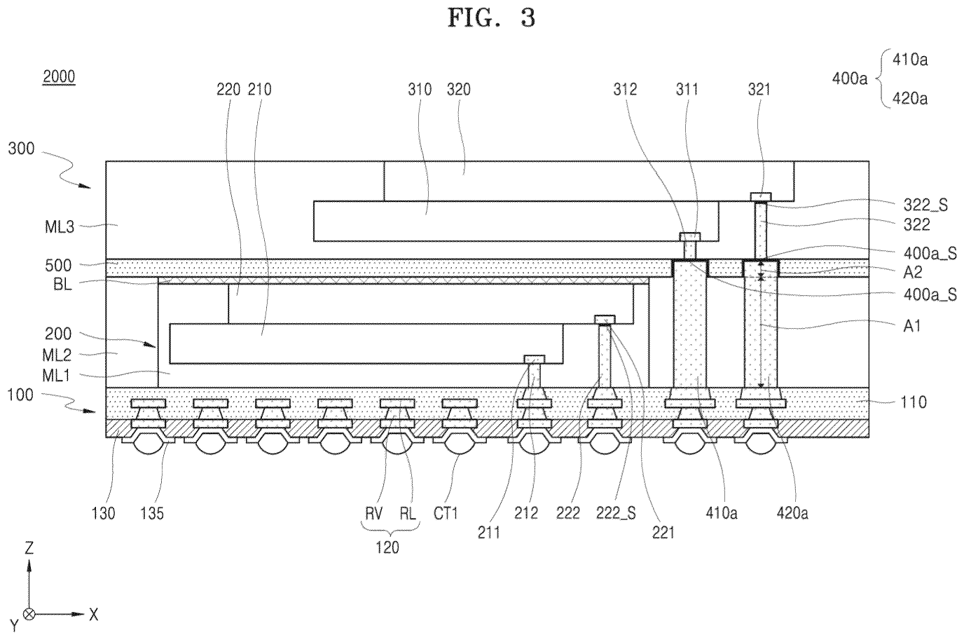

FIG. 3 is a schematic cross-sectional view of a semiconductor package 2000 according to one or more embodiments.

Most of components constituting the semiconductor package 2000 described below and materials constituting the components are substantially identical or similar to those described above with reference to FIG. 1. Accordingly, for convenience of description, differences between the semiconductor package 2000 of FIG. 3 and the semiconductor package 1000 of FIG. 1 described above will be mainly described.

Referring to FIG. 3, the semiconductor package 2000 may include a redistribution structure 100, a first chip structure 200, a second lower molding layer ML2, an intermediate insulating layer 500, a plurality of conductive posts 400a, and a second chip structure 300.

The intermediate insulating layer 500 may be located on the first chip structure 200 and the second lower molding layer ML2. The second chip structure 300 may be located on the intermediate insulating layer 500. An upper molding layer ML3 of the second chip structure 300 may be spaced apart from the first chip structure 200 and the second lower molding layer ML2 with the intermediate insulating layer 500 therebetween. A side surface of the intermediate insulating layer 500, an outer surface of the second lower molding layer ML2, and a side surface of the upper molding layer ML3 may be coplanar with each other.

A bonding layer BL of the first chip structure 200 may be in contact with the intermediate insulating layer 500. For example, the first chip structure 200 may be attached to the intermediate insulating layer 500 through the bonding layer BL. In one or more embodiments, the bonding layer BL may include an adhesive film, such as a DAF. In one or more embodiments, the first chip structure 200 and the intermediate insulating layer 500 may be bonded to each other through an oxide bonding method, and the bonding layer BL may include silicon oxide.

The plurality of conductive posts 400a may be located on the redistribution structure 100. The plurality of conductive posts 400a may be spaced apart from the first chip structure 200 in the horizontal direction. The plurality of conductive posts 400a may penetrate the intermediate insulating layer 500 and the second lower molding layer ML2. For example, the plurality of conductive posts 400a may extend in the vertical direction (Z direction) from an upper surface of the intermediate insulating layer 500 to a lower surface of the second lower molding layer ML2.

In one or more embodiments, the height of each of the plurality of conductive posts 400a in the vertical direction (Z direction) may be greater than the height of the first chip structure 200 in the vertical direction (Z direction). The height of each of the plurality of conductive posts 400a in the vertical direction (Z direction) may be substantially equal to the sum of the height of the second lower molding layer ML2 in the vertical direction (Z direction) and the height of the intermediate insulating layer 500 in the vertical direction (Z direction).

In one or more embodiments, the width of each of the plurality of conductive posts 400a in the horizontal direction may be greater than the width of each of a second lower chip post 222 and a second upper chip post 322 in the horizontal direction. For example, through holes in which the plurality of conductive posts 400a are formed may be formed through a drilling process, and through holes in which the second lower chip post 222 and the second upper chip post 322 are formed may be formed through a photo process, and thus, the width of each of the plurality of conductive posts 400a and the width of each of the second lower chip post 222 and the second upper chip post 322 may be different from each other in the horizontal direction.

In one or more embodiments, the plurality of conductive posts 400a may include a first conductive post 410a in contact with the first upper chip post 312 and a second conductive post 420a in contact with the second upper chip post 322. For example, a distance between the second conductive post 420a and the first chip structure 200 in the horizontal direction may be greater than a distance between the first conductive post 410a and the first chip structure 200 in the horizontal direction.

In one or more embodiments, each of the plurality of conductive posts 400a may be divided into a first portion A1 and a second portion A2. For example, the first portion A1 of each of the plurality of conductive posts 400a may be a portion of each of the plurality of conductive posts 400a which penetrates the second lower molding layer ML2, and the second portion A2 of each of the plurality of conductive posts 400a may be a portion of each of the plurality of conductive posts 400a which penetrates the intermediate insulating layer 500. Side surfaces of the first portion A1 of each of the plurality of conductive posts 400a may be in contact with the second lower molding layer ML2, and side surfaces of the second portion A2 of each of the plurality of conductive posts 400a may be in contact with the intermediate insulating layer 500.

In one or more embodiments, the width of each of the plurality of conductive posts 400a in the first portion A1 of each of the plurality of conductive posts 400a may be substantially equal to the width of each of the plurality of conductive posts 400a in the second portion A2 of each of the plurality of conductive posts 400a in the horizontal direction.

In one or more embodiments, a first seed layer 400a_S may be located between each of the plurality of conductive posts 400a and the intermediate insulating layer 500 and on an upper surface of each of the plurality of conductive posts 400a. For example, the first seed layer 400a_S may be located on portions of side surfaces of each of the plurality of conductive posts 400a, which are surrounded by the intermediate insulating layer 500, and on the upper surface of each of the plurality of conductive posts 400a. For example, the first seed layer 400a_S may conformally be provided on and cover surfaces of the second portion A2 of each of the plurality of conductive posts 400a.

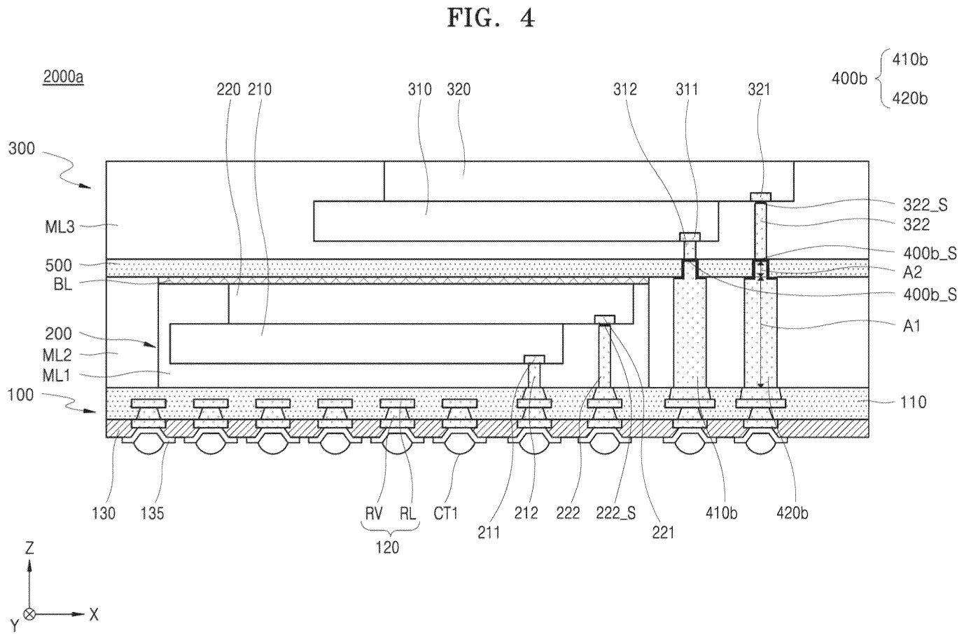

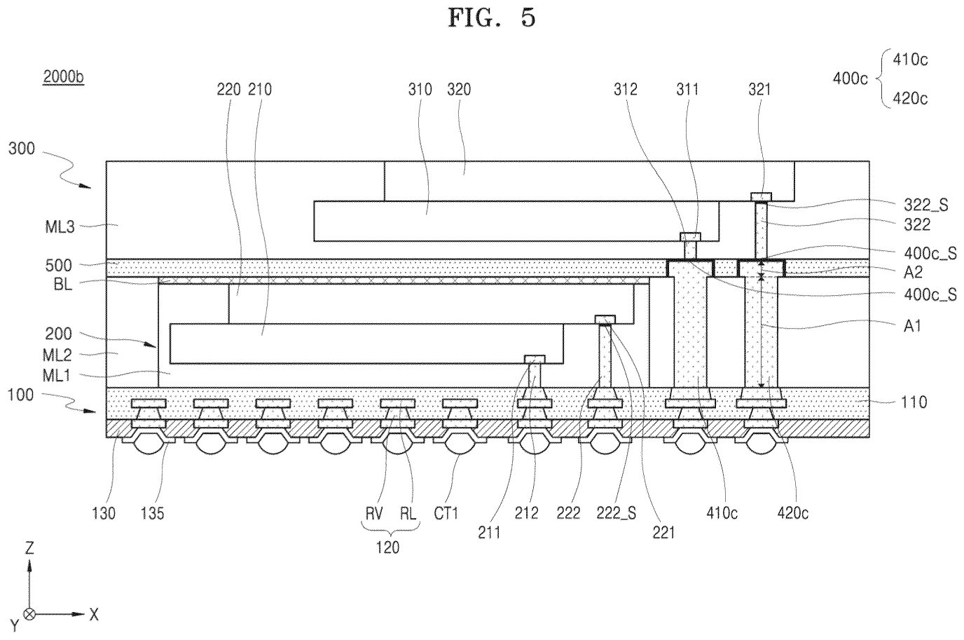

FIG. 4 is a schematic cross-sectional view of a semiconductor package 2000a according to one or more embodiments. FIG. 5 is a schematic cross-sectional view of a semiconductor package 2000b according to one or more embodiments.

Most of components constituting the semiconductor packages 2000a and 2000b described below and materials constituting the components are substantially identical or similar to those described above with reference to FIG. 3. Accordingly, for convenience of description, differences between the semiconductor packages 2000a and 2000b of FIGS. 4 and 5 and the semiconductor package 2000 of FIG. 3 described above will be mainly described.

Referring to FIG. 4, the semiconductor package 2000a may include a redistribution structure 100, a first chip structure 200, a second lower molding layer ML2, an intermediate insulating layer 500, a plurality of conductive posts 400b, and a second chip structure 300.

The intermediate insulating layer 500 may be located between the first chip structure 200 and the second chip structure 300. For example, the intermediate insulating layer 500 may be located on the first chip structure 200 and the second lower molding layer ML2. An upper molding layer ML3 of the second chip structure 300 may be located on the intermediate insulating layer 500.

In one or more embodiments, a bonding layer BL of the first chip structure 200 may be in contact with the intermediate insulating layer 500. For example, the first chip structure 200 may be attached to the intermediate insulating layer 500 through the bonding layer BL.

The plurality of conductive posts 400b may be spaced apart from the first chip structure 200 in the horizontal direction and may be located on the redistribution structure 100. The plurality of conductive posts 400b may penetrate the intermediate insulating layer 500 and the second lower molding layer ML2.

In one or more embodiments, each of the plurality of conductive posts 400b may be divided into a first portion A1 and a second portion A2. For example, the first portion A1 of each of the plurality of conductive posts 400b may be a portion of each of the plurality of conductive posts 400b which penetrates the second lower molding layer ML2, and the second portion A2 of each of the plurality of conductive posts 400b may be a portion of each of the plurality of conductive posts 400b which penetrates the intermediate insulating layer 500.

In one or more embodiments, the width of each of the plurality of conductive posts 400b in the first portion A1 of each of the plurality of conductive posts 400b may be different from the width of each of the plurality of conductive posts 400b in the second portion A2 of each of the plurality of conductive posts 400b in the horizontal direction. For example, the width of each of the plurality of conductive posts 400b in the first portion A1 of each of the plurality of conductive posts 400b may be greater than the width of each of the plurality of conductive posts 400b in the second portion A2 of each of the plurality of conductive posts 400b in the horizontal direction. For example, a portion of an upper surface of the first portion A1 of each of the plurality of conductive posts 400b may face the intermediate insulating layer 500.

In one or more embodiments, the plurality of conductive posts 400b may include a first conductive post 410b and a second conductive post 420b. The width of the first conductive post 410b in the second portion A2 of the first conductive post 410b may be greater than the width of a first upper chip post 312 in the horizontal direction. The width of the second conductive post 420b in the second portion A2 of the second conductive post 420b may be greater than the width of a second upper chip post 322 in the horizontal direction.

In one or more embodiments, a first seed layer 400b_S may be located between each of the plurality of conductive posts 400b and the intermediate insulating layer 500 and on an upper surface of each of the plurality of conductive posts 400b. For example, the first seed layer 400b_S may be located on portions of side surfaces of each of the plurality of conductive posts 400b, which are surrounded by the intermediate insulating layer 500, and on the upper surface of each of the plurality of conductive posts 400b.

For example, a portion of the first seed layer 400b_S may be in contact with a lower surface of the intermediate insulating layer 500. A portion of the first seed layer 400b_S may be located between the upper surface of the first portion A1 of each of the plurality of conductive posts 400b and the intermediate insulating layer 500. For example, the first seed layer 400b_S may be provided on and cover side and upper surfaces of the second portion A2 of each of the plurality of conductive posts 400b and may be provided on and cover a portion of the lower surface of the intermediate insulating layer 500, which is located on the first portion A1 of each of the plurality of conductive posts 400b.

Referring to FIG. 5, the semiconductor package 2000b may include a redistribution structure 100, a first chip structure 200, a second lower molding layer ML2, an intermediate insulating layer 500, a plurality of conductive posts 400c, and a second chip structure 300.

The intermediate insulating layer 500 may be located between the first chip structure 200 and the second chip structure 300. For example, the intermediate insulating layer 500 may be located on the first chip structure 200 and the second lower molding layer ML2. The second chip structure 300 may be located on the intermediate insulating layer 500.

In one or more embodiments, a bonding layer BL of the first chip structure 200 may be in contact with the intermediate insulating layer 500. For example, the first chip structure 200 may be attached to the intermediate insulating layer 500 through the bonding layer BL.

The plurality of conductive posts 400c may be spaced apart from the first chip structure 200 in the horizontal direction and may be located on the redistribution structure 100. The plurality of conductive posts 400c may penetrate the intermediate insulating layer 500 and the second lower molding layer ML2.

In one or more embodiments, the width of each of the plurality of conductive posts 400c in a first portion A1 of each of the plurality of conductive posts 400c may be less than the width of each of the plurality of conductive posts 400c in a second portion A2 of each of the plurality of conductive posts 400c in the horizontal direction. For example, a portion of a lower surface of the second portion A2 of each of the plurality of conductive posts 400c may be in contact with the second lower molding layer ML2.

In one or more embodiments, the plurality of conductive posts 400c may include a first conductive post 410c and a second conductive post 420c. For example, the width of the first conductive post 410c in the first portion A1 of the first conductive post 410c may be less than the width of the first conductive post 410c in the second portion A2 of the first conductive post 410c and greater than the width of a first upper chip post 312 in the horizontal direction. The width of the second conductive post 420c in the first portion A1 of the second conductive post 420c may be less than the width of the second conductive post 420c in the second portion A2 of the second conductive post 420c and greater than the width of a second upper chip post 322 in the horizontal direction.

In one or more embodiments, a first seed layer 400c_S may be located between each of the plurality of conductive posts 400c and the intermediate insulating layer 500 and on an upper surface of each of the plurality of conductive posts 400c. For example, the first seed layer 400c_S may be located on portions of side surfaces of each of the plurality of conductive posts 400c, which are surrounded by the intermediate insulating layer 500, and on the upper surface of each of the plurality of conductive posts 400c.

For example, the first seed layer 400c_S may be formed on side and upper surfaces of the second portion A2 of each of the plurality of conductive posts 400c, which are in contact with the intermediate insulating layer 500. The first seed layer 400c_S may not be formed on a lower surface of the second portion A2 of each of the plurality of conductive posts 400c, which is in contact with the second lower molding layer ML2.

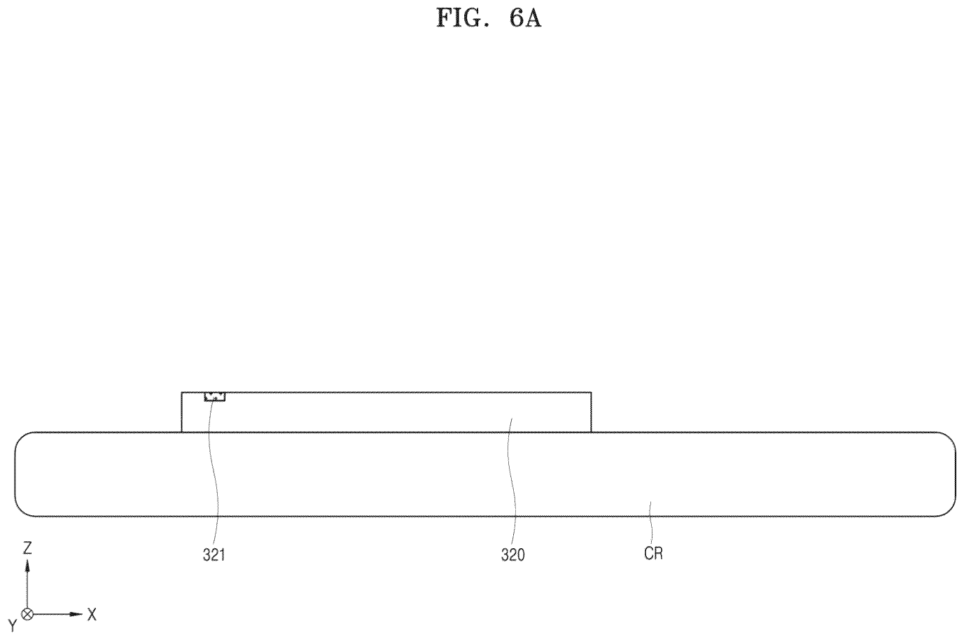

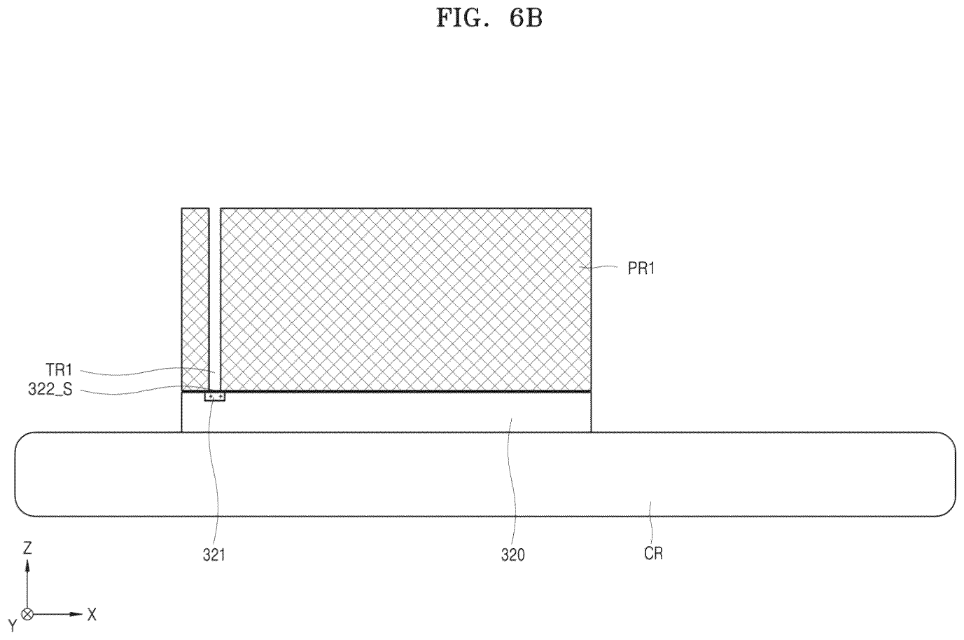

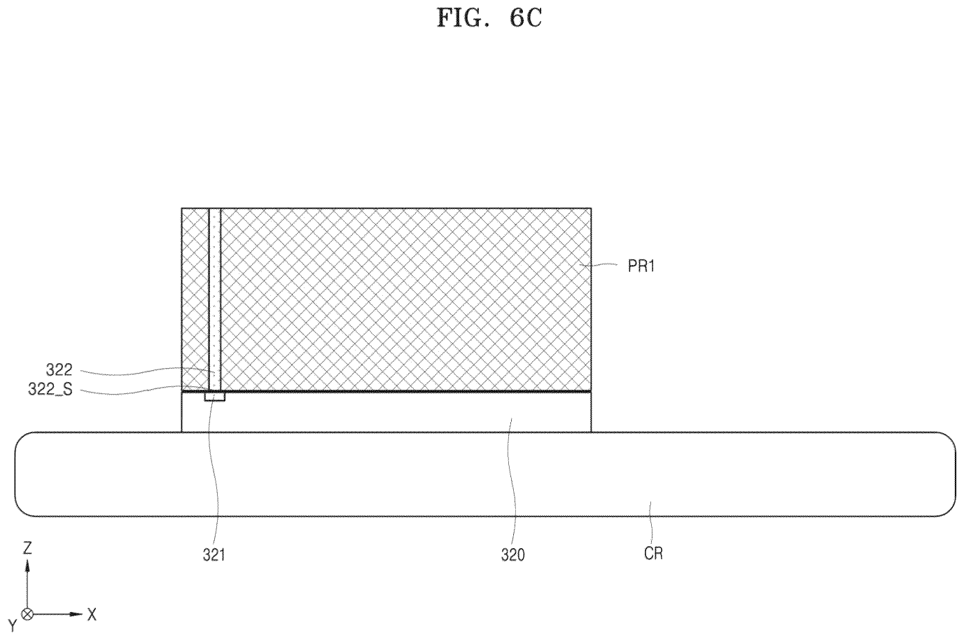

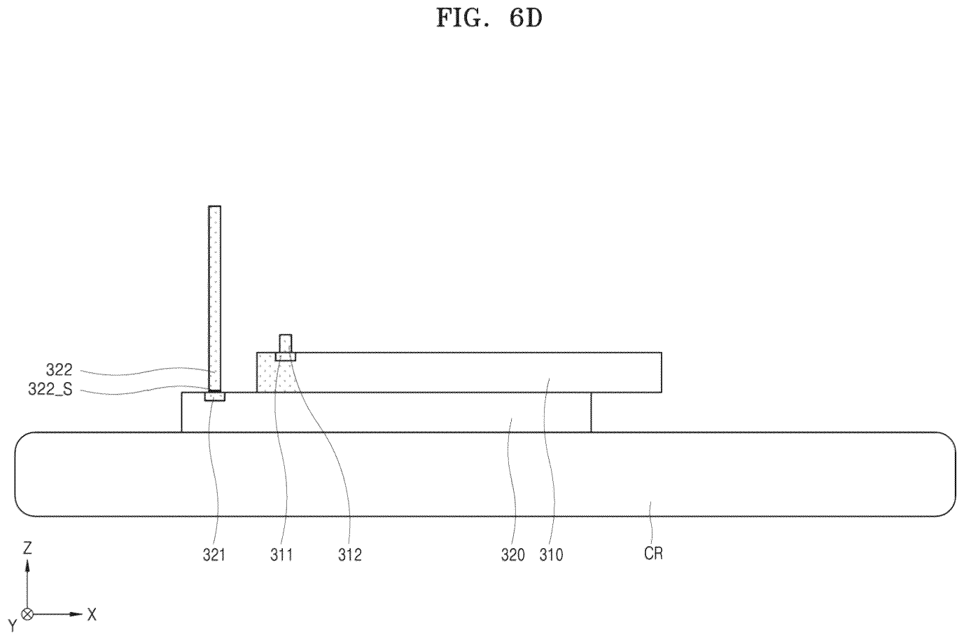

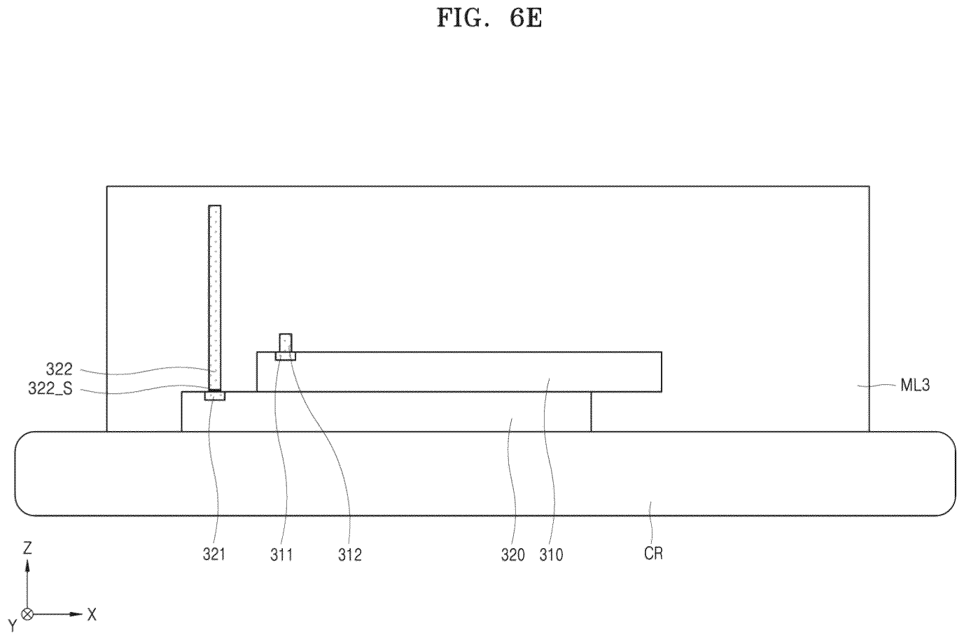

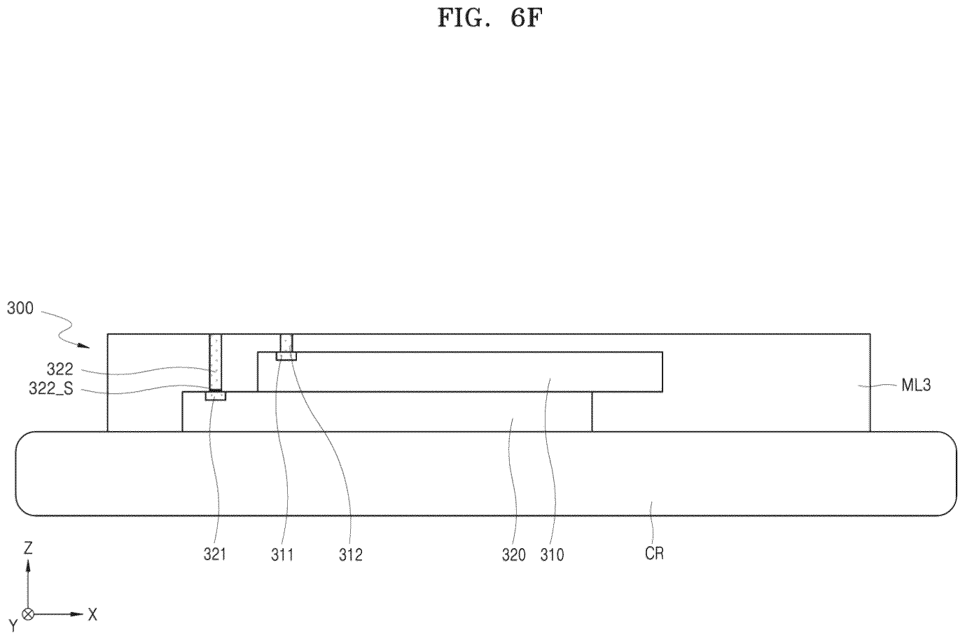

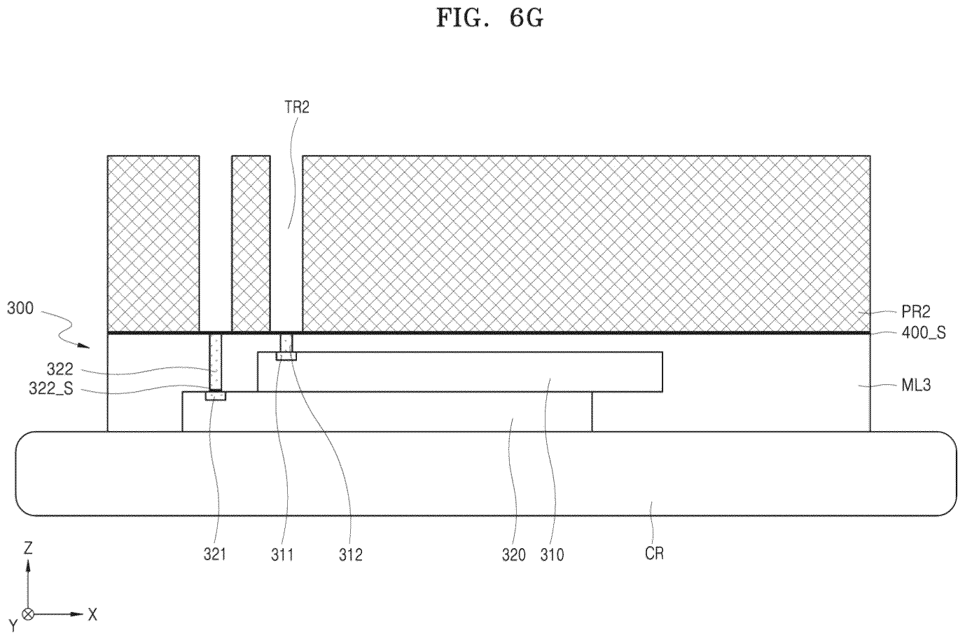

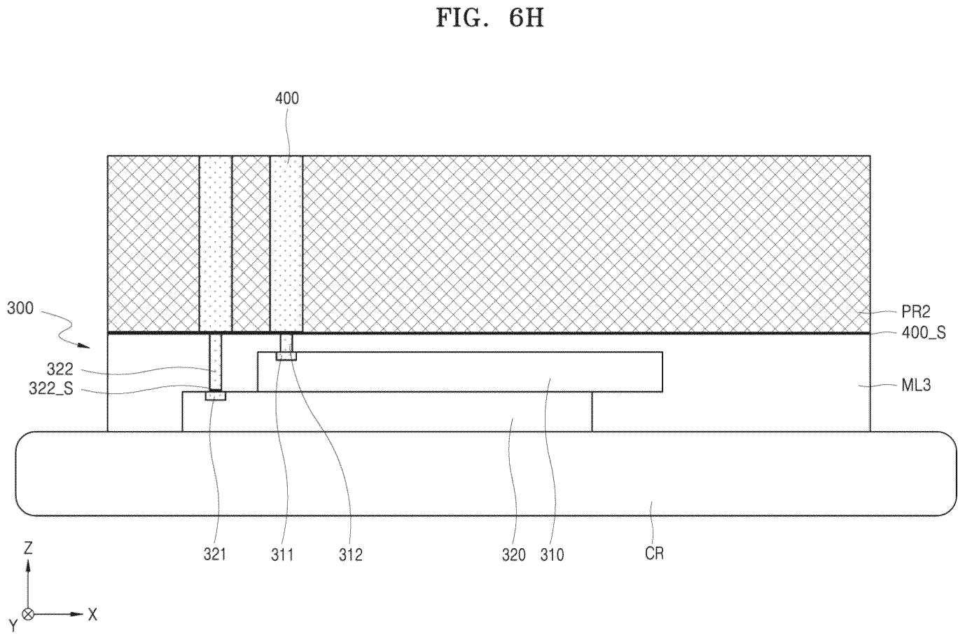

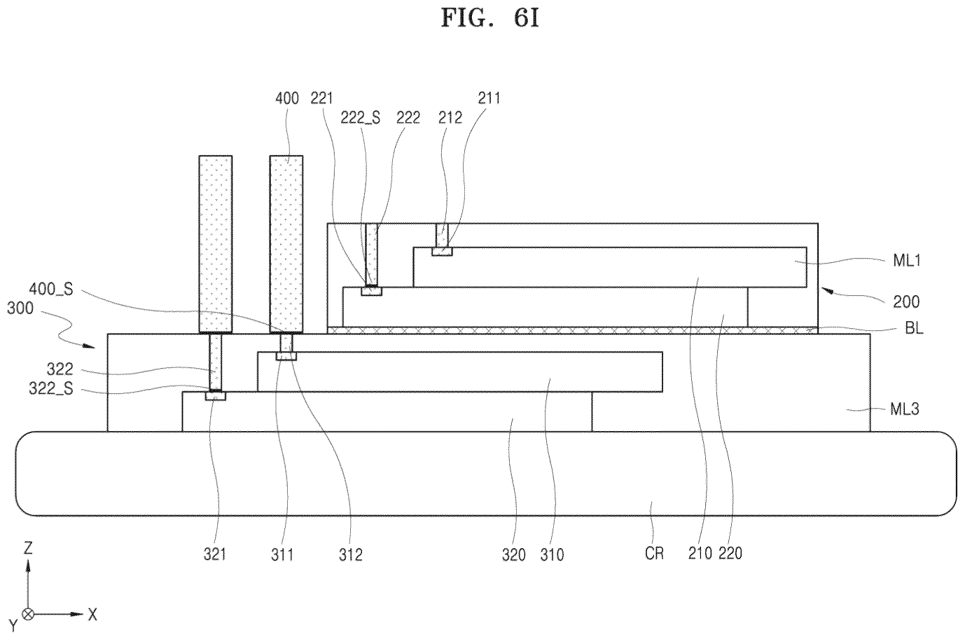

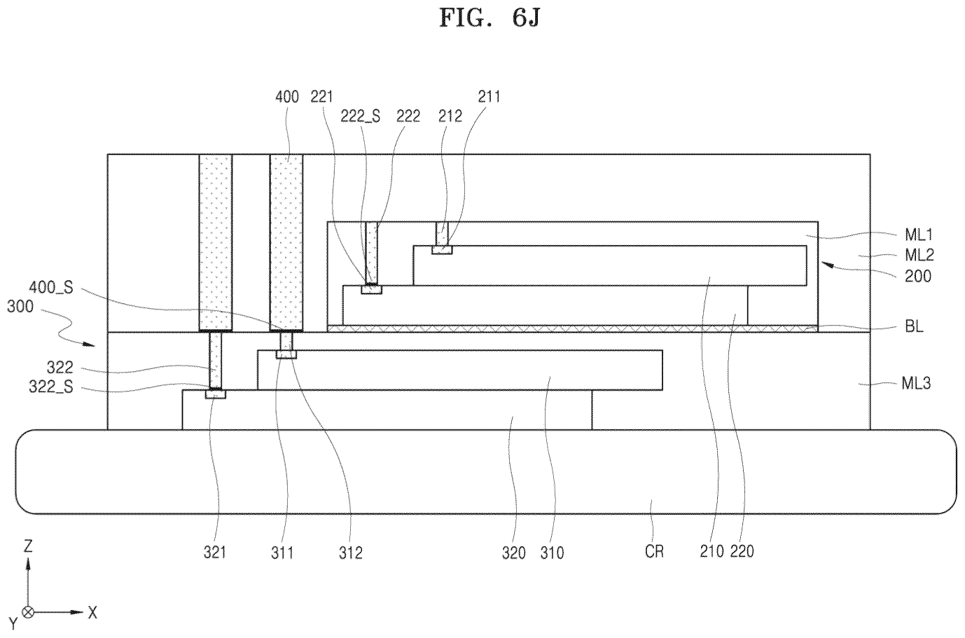

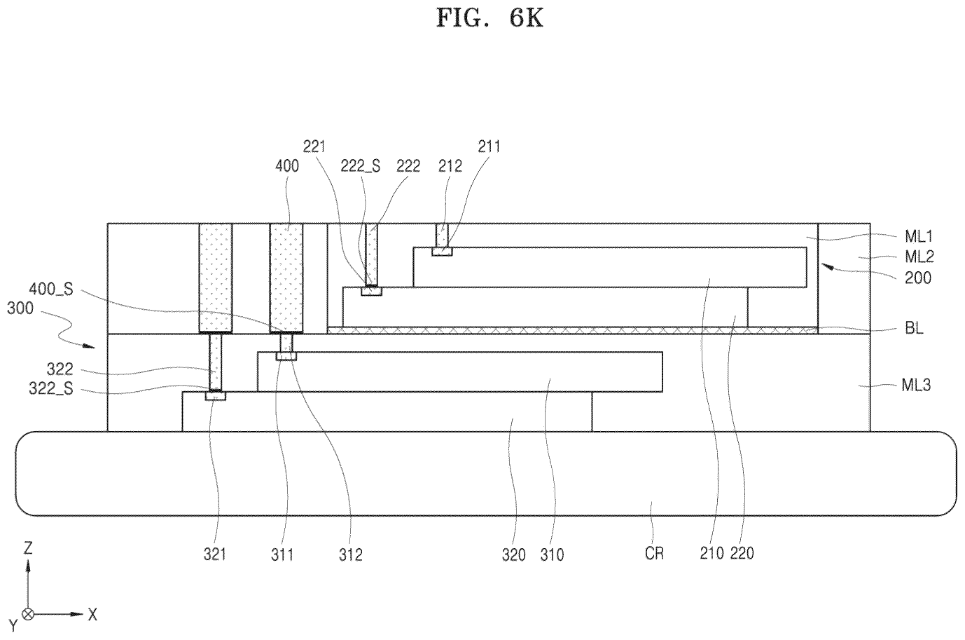

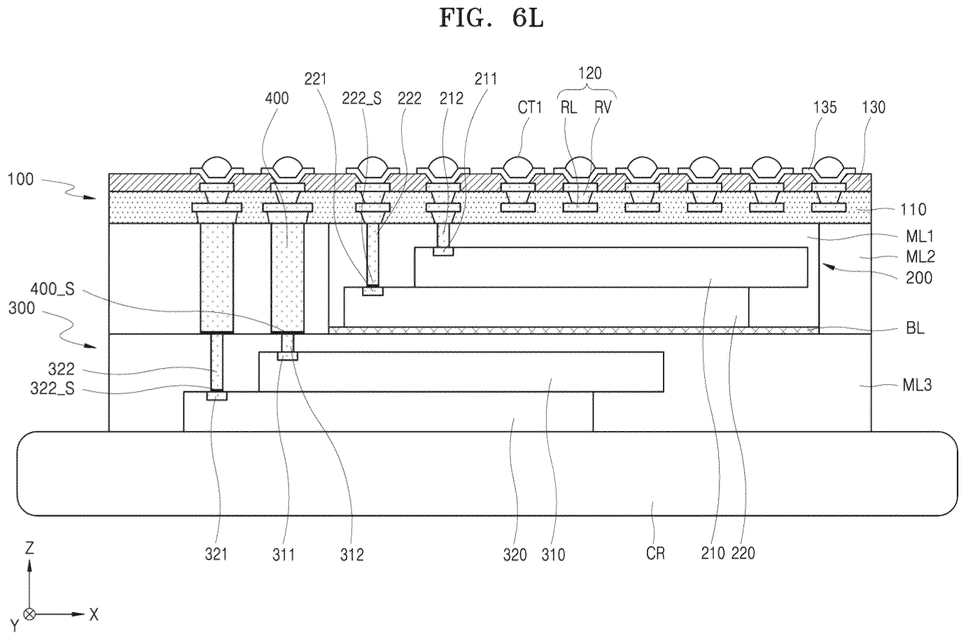

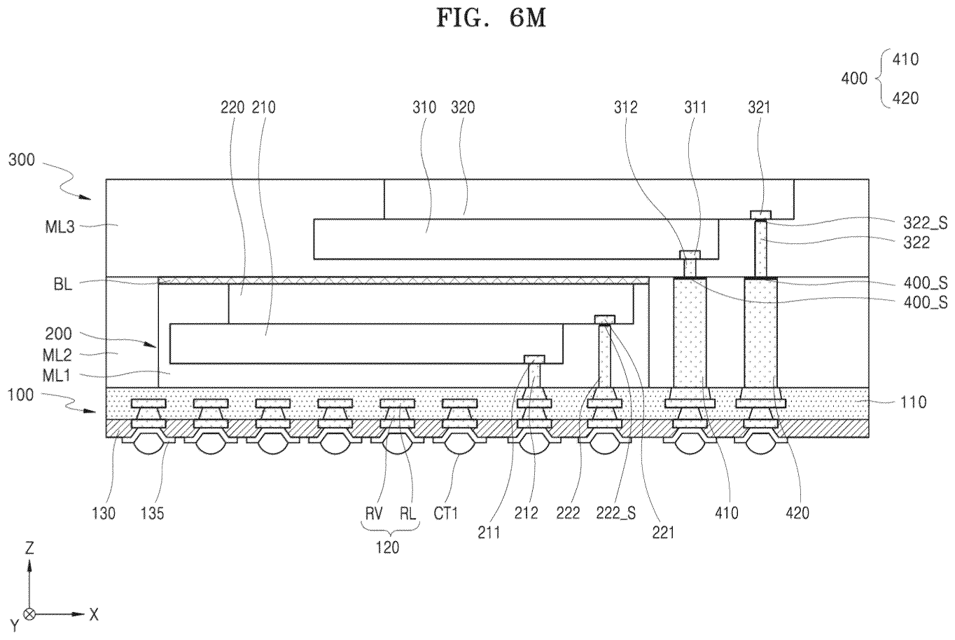

FIGS. 6A to 6M are cross-sectional views illustrating, according to a process sequence, a method of manufacturing the semiconductor package 1000, according to one or more embodiments.

Referring to FIGS. 6A to 6F, a second chip structure 300 may be manufactured on a carrier substrate CR.

Referring to FIG. 6A, a second upper semiconductor chip 320 may be attached onto the carrier substrate CR. For example, the second upper semiconductor chip 320 may be attached onto the carrier substrate CR through an adhesive insulating layer. The second upper semiconductor chip 320 may include an active surface opposite to the carrier substrate CR and an inactive surface facing the active surface. The second upper semiconductor chip 320 may be attached onto the carrier substrate CR such that the inactive surface of the second upper semiconductor chip 320 faces the carrier substrate CR. For example, an I/O pad 321 located on the active surface of the second upper semiconductor chip 320 may be spaced apart from the carrier substrate CR in the vertical direction (Z direction).

For example, the carrier substrate CR may include glass, silicon, or aluminum oxide. The adhesive insulating layer may be, for example, an adhesive tape of which the adhesive strength is weakened by heat treatment or laser irradiation.

Referring to FIG. 6B, an upper seed layer 322_S may be formed on the second upper semiconductor chip 320. For example, the upper seed layer 322_S may be conformally formed on an upper surface of the second upper semiconductor chip 320. For example, the upper seed layer 322_S may be formed through a metal deposition process, such as physical vapor deposition (PVD), chemical vapor deposition (CVD), or atomic layer deposition (ALD).

Next, a first photoresist PR1 may be formed to be provided on and cover an upper portion of the second upper semiconductor chip 320, and then, through a photo process, a first trench TR1 extending from an upper surface of the first photoresist PRI to a lower surface of the first photoresist PR1 may be formed. The first photoresist PRI may be in contact with the upper seed layer 322_S. The first trench TR1 may be located above the I/O pad 321 of the second upper semiconductor chip 320, and thus, a portion of the upper seed layer 322_S, which is located on the I/O pad 321 of the second upper semiconductor chip 320, may be exposed to the outside.

Referring to FIG. 6C, through an electrolytic plating process, the first trench TR1 may be filled with a conductive material to form a second upper chip post 322. For example, in an electrolytic plating process, the first trench TR1 may be filled with a conductive material by using the upper seed layer 322_S as a starting point.

Referring to FIG. 6D, in the result of FIG. 6C, the first photoresist PR1 may be removed, and a portion of the upper seed layer 322_S may be removed. For example, portions of the upper seed layer 322_S which are exposed to the outside by removing the first photoresist PR1, that is, portions of the upper seed layer 322_S which are located below the first photoresist PR1, may be removed.

Next, a first upper semiconductor chip 310 may be attached onto the second upper semiconductor chip 320. For example, the first upper semiconductor chip 310 may be attached onto the second upper semiconductor chip 320 through an adhesive film, such as a DAF.

The first upper semiconductor chip 310 may include an active surface opposite to the second upper semiconductor chip 320 and an inactive surface facing the active surface. The first upper semiconductor chip 310 may be attached onto the second upper semiconductor chip 320 such that the inactive surface of the first upper semiconductor chip 310 faces the second upper semiconductor chip 320. For example, an I/O pad 311 of the first upper semiconductor chip 310, which is located on the active surface of the first upper semiconductor chip 310, may be spaced apart from the second upper semiconductor chip 320 in the vertical direction (Z direction).

The first upper semiconductor chip 310 may be attached onto the second upper semiconductor chip 320 so as to be offset from the second upper semiconductor chip 320. For example, the first upper semiconductor chip 310 may be offset-stacked on the second upper semiconductor chip 320 such that the first upper semiconductor chip 310 is not provided on and does not cover the I/O pad 321 of the second upper semiconductor chip 320.

A first upper chip post 312 may be attached onto the I/O pad 311 of the first upper semiconductor chip 310. The first upper semiconductor chip 310 may be attached onto the second upper semiconductor chip 320 with the first upper chip post 312 pre-attached thereon. In one or more embodiments, the first upper chip post 312 may be manufactured on the first upper semiconductor chip 310 in a manner identical to that used to manufacture the second upper chip post 322 on the second upper semiconductor chip 320. In one or more embodiments, the first upper chip post 312 may be separately manufactured and then attached onto the first upper semiconductor chip 310.

Referring to FIGS. 6E and 6F, an upper molding layer ML3 may be formed to be provided on and cover the first upper semiconductor chip 310, the first upper chip post 312, the second upper semiconductor chip 320, and the second upper chip post 322. For example, the upper molding layer ML3 may be formed such that the second upper chip post 322 is buried inside the upper molding layer ML3.

Thereafter, through a polishing process, a portion of the upper molding layer ML3 may be removed so that the second upper chip post 322 is exposed to the outside. Accordingly, an upper surface of the first upper chip post 312, an upper surface of the second upper chip post 322, and an upper surface of the upper molding layer ML3 may be coplanar with each other.

Referring to FIGS. 6G and 6H, a plurality of conductive posts 400 may be formed on the upper molding layer ML3.

Referring to FIG. 6G, a first seed layer 400_S may be formed on the upper surface of the upper molding layer ML3. For example, the first seed layer 400_S may be conformally formed on the upper surface of the upper molding layer ML3. A second photoresist PR2 may be formed on the first seed layer 400_S to be provided on and cover the first seed layer 400_S, and then, through a photo process, second trenches TR2 extending from an upper surface of the second photoresist PR2 to a lower surface of the second photoresist PR2 may be formed.

One of the second trenches TR2 may be located above the first upper chip post 312, and another one of the second trenches TR2 may be located above the second upper chip post 322. For example, portions of the first seed layer 400_S, which are located on the first upper chip post 312 and the second upper chip post 322, may be exposed to the outside by the second trenches TR2.

Referring to FIG. 6H, through an electrolytic plating process, a conductive material may be filled in the second trenches TR2 to thereby form a plurality of conductive posts 400. For example, in an electrolytic plating process, the second trenches TR2 may be filled with a conductive material by using the first seed layer 400_S as a starting point.

Thereafter, the second photoresist PR2 may be removed, and a portion of the first seed layer 400_S may be removed. For example, portions of the first seed layer 400_S which are exposed to the outside by removing the second photoresist PR2, that is, portions of the first seed layer 400_S which are located below the second photoresist PR2, may be removed. For example, portions of the first seed layer 400_S which are located below the plurality of conductive posts 400 may not be removed.

Referring to FIG. 6I, a first chip structure 200 may be attached onto the upper molding layer ML3. The first chip structure 200, which may be pre-manufactured on a separate carrier substrate, may be attached onto the second chip structure 300. The first chip structure 200 may be attached onto the upper molding layer ML3 of the second chip structure 300 through a bonding layer BL. For example, the bonding layer BL may be located between the first chip structure 200 and the upper molding layer ML3.

The first chip structure 200 may be spaced apart from the plurality of conductive posts 400 in the horizontal direction. For example, the first chip structure 200 may not overlap the I/O pad 311 of the first upper semiconductor chip 310 and the I/O pad 321 of the second upper semiconductor chip 320 in the vertical direction.

The first chip structure 200 may include a first lower semiconductor chip 210, a first lower chip post 212, a second lower semiconductor chip 220, a second lower chip post 222, and a first lower molding layer ML1. For example, the second lower semiconductor chip 220 and the second lower chip post 222 of the first chip structure 200 may respectively correspond to the second upper semiconductor chip 320 and the second upper chip post 322 of the second chip structure 300. The first lower semiconductor chip 210 and the first lower chip post 212 of the first chip structure 200 may respectively correspond to the first upper semiconductor chip 310 and the first upper chip post 312 of the second chip structure 300.

The first chip structure 200 may be manufactured through a manufacturing process that is substantially identical to the manufacturing process of the second chip structure 300 described above with reference to FIGS. 6A to 6F. For example, the first chip structure 200 may be manufactured by dicing the second chip structure 300 of FIG. 6F. For example, the size of the first lower molding layer ML1 of the first chip structure 200 may be less than the size of the upper molding layer ML3.

Referring to FIGS. 6J and 6K, a second lower molding layer ML2 may be formed to be provided on and cover the plurality of conductive posts 400 and the first chip structure 200. For example, the first chip structure 200 may be buried inside the second lower molding layer ML2.

An interface may be present between the first lower molding layer ML1 of the first chip structure 200 and the second lower molding layer ML2. Because the first chip structure 200 manufactured on a separate carrier substrate is attached onto the second chip structure 300 and then the second lower molding layer ML2 is formed to be provided on and cover the first chip structure 200, there may be a difference in curing time between the first lower molding layer ML1 of the first chip structure 200 and the second lower molding layer ML2. Due to the difference in curing time, even when the first lower molding layer ML1 and the second lower molding layer ML2 include identical constituent materials, an interface may be present between the first lower molding layer ML1 and the second lower molding layer ML2.

Thereafter, the second lower molding layer ML2 may be removed until an upper surface of the first chip structure 200 is exposed to the outside. For example, the first lower chip post 212 of the first chip structure 200, the second lower chip post 222 of the first chip structure 200, and the plurality of conductive posts 400 may be exposed to the outside.

For example, an upper surface of the second lower molding layer ML2, an upper surface of each of the plurality of conductive posts 400, an upper surface of the first lower molding layer ML1 of the first chip structure 200, an upper surface of the first lower chip post 212 of the first chip structure 200, and an upper surface of the second lower chip post 222 of the first chip structure 200 may be coplanar with each other.

Referring to FIG. 6L, a redistribution structure 100 may be formed on the result of FIG. 6K. The redistribution structure 100 may include redistribution patterns 120 and a redistribution insulating layer 110 surrounding the redistribution patterns 120. Thereafter, a passivation layer 130 and lower metal layers 135 may be formed on the redistribution structure 100. Thereafter, external connection terminals CT1 may be attached onto the lower metal layers 135.

For example, the redistribution structure 100 may be formed such that redistribution vias RV of the redistribution patterns 120 of the redistribution structure 100 are in contact with the plurality of conductive posts 400, the first lower chip post 212 of first chip structure 200, and the second lower chip post 222 of the first chip structure 200. For example, each of the redistribution vias RV may be formed to have a width in the horizontal direction that decreases downward in the vertical direction (Z direction). For example, the width of each of the redistribution via RV in the horizontal direction may decrease in the horizontal direction toward the upper surface of the first chip structure 200. Referring to FIG. 6M, the upper molding layer ML3 and the second upper semiconductor chip 320 may be separated from the carrier substrate CR to thereby manufacture a semiconductor package 1000.

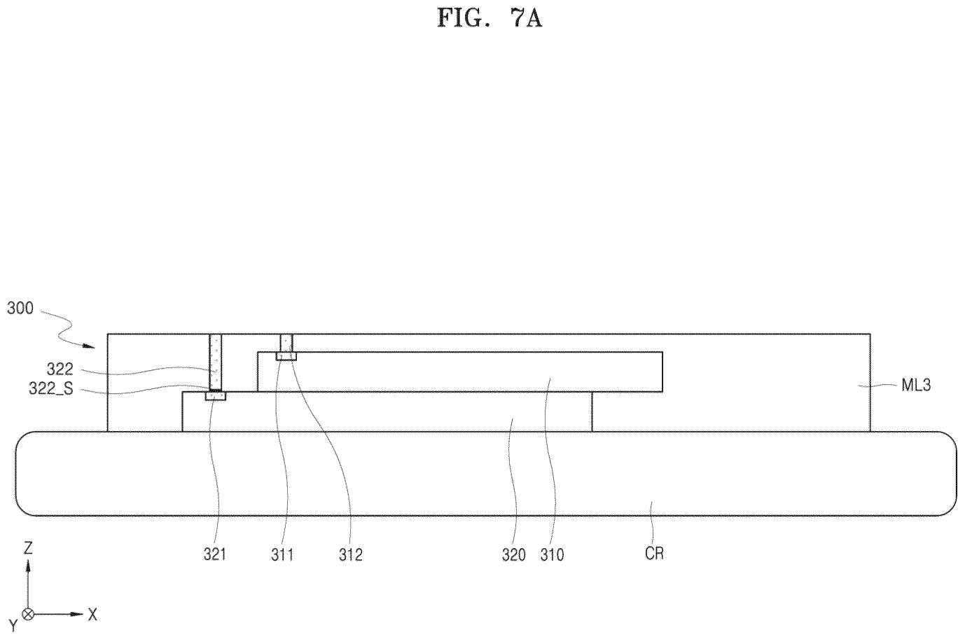

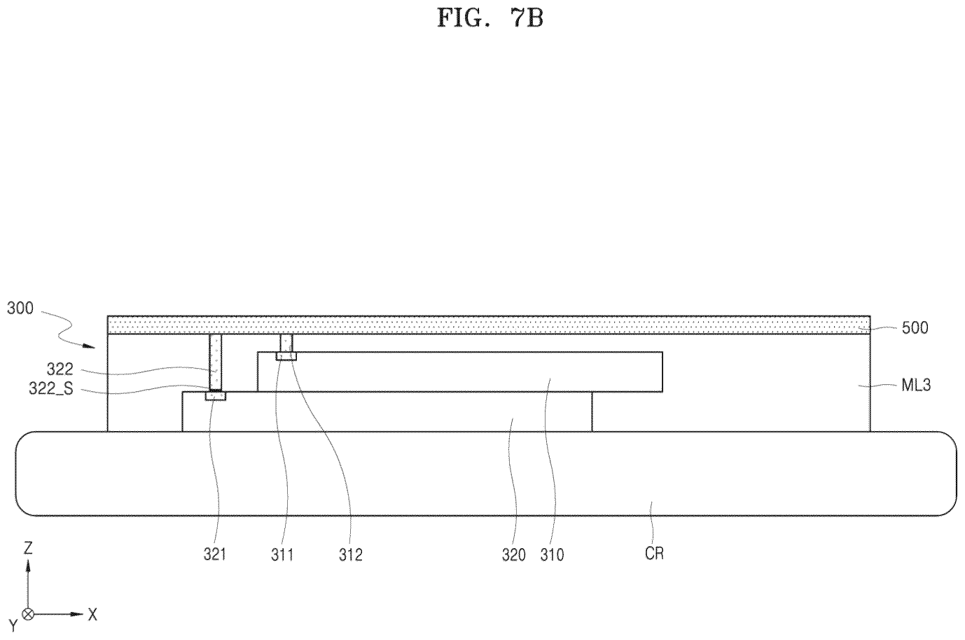

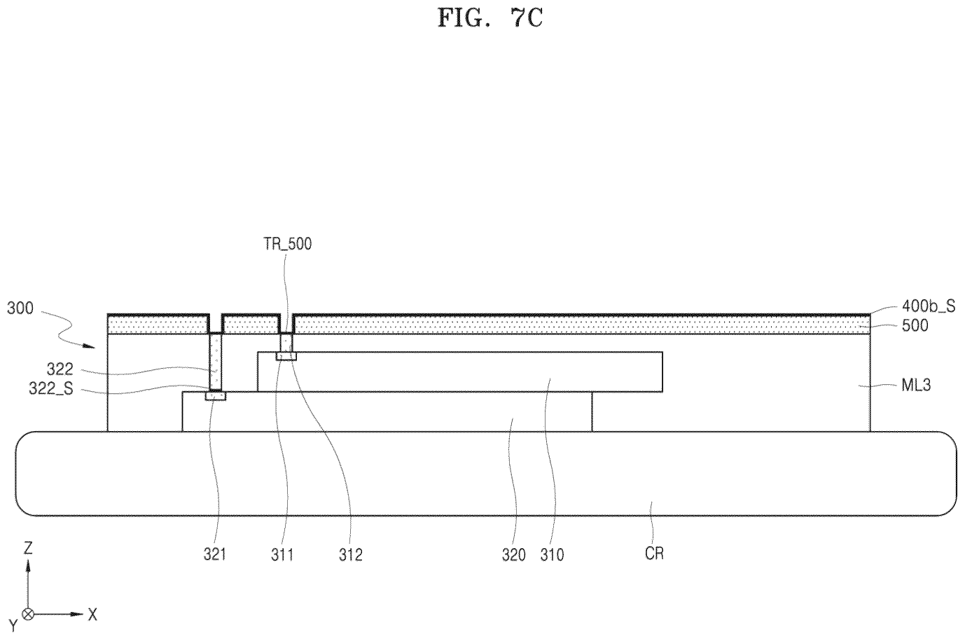

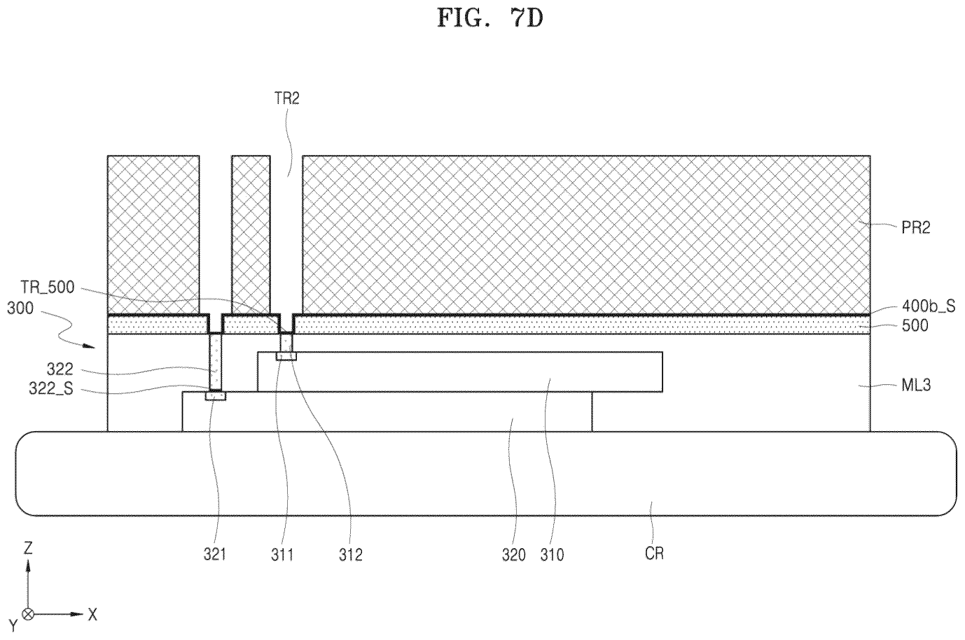

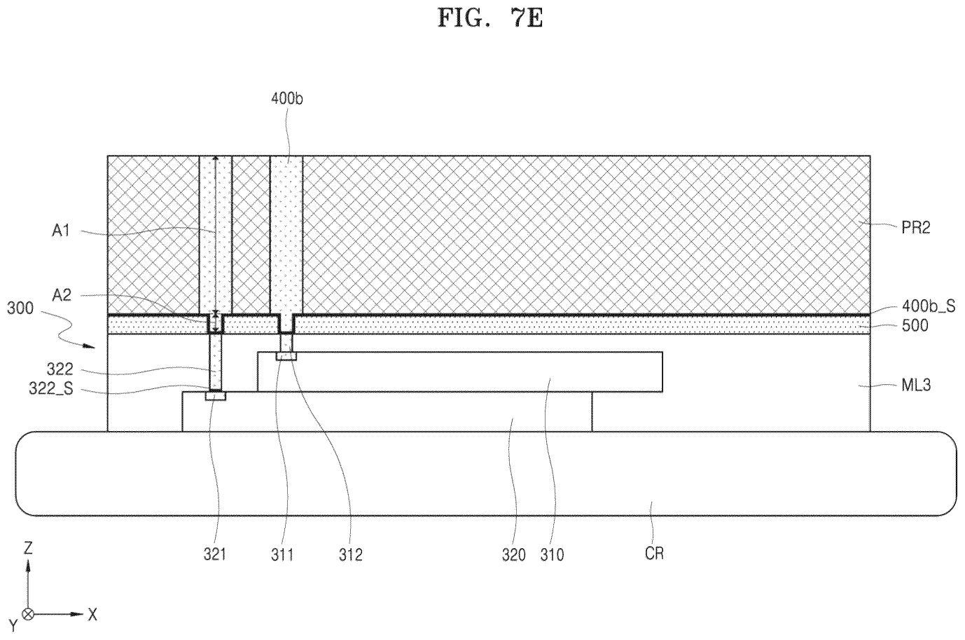

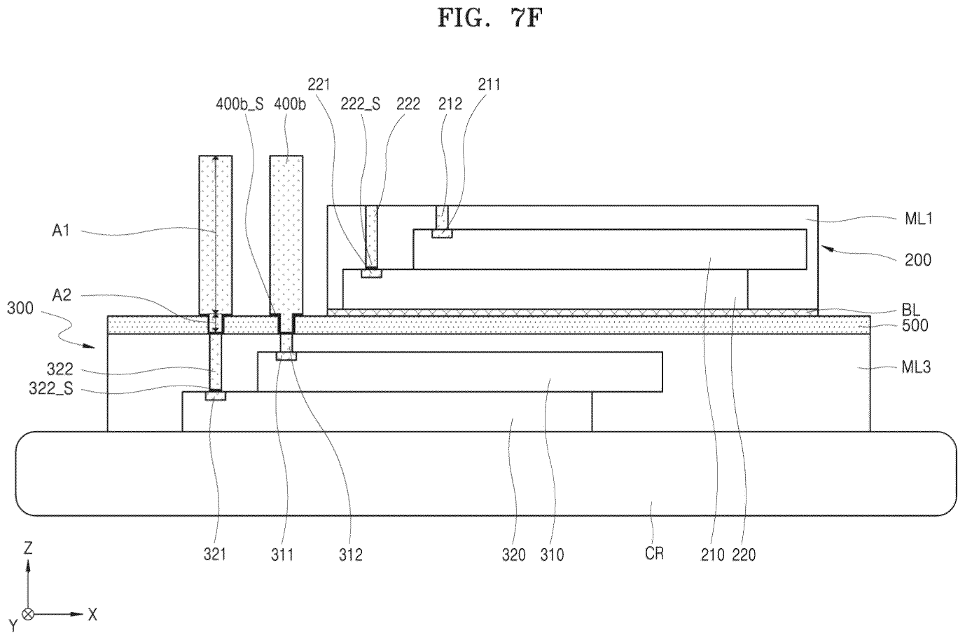

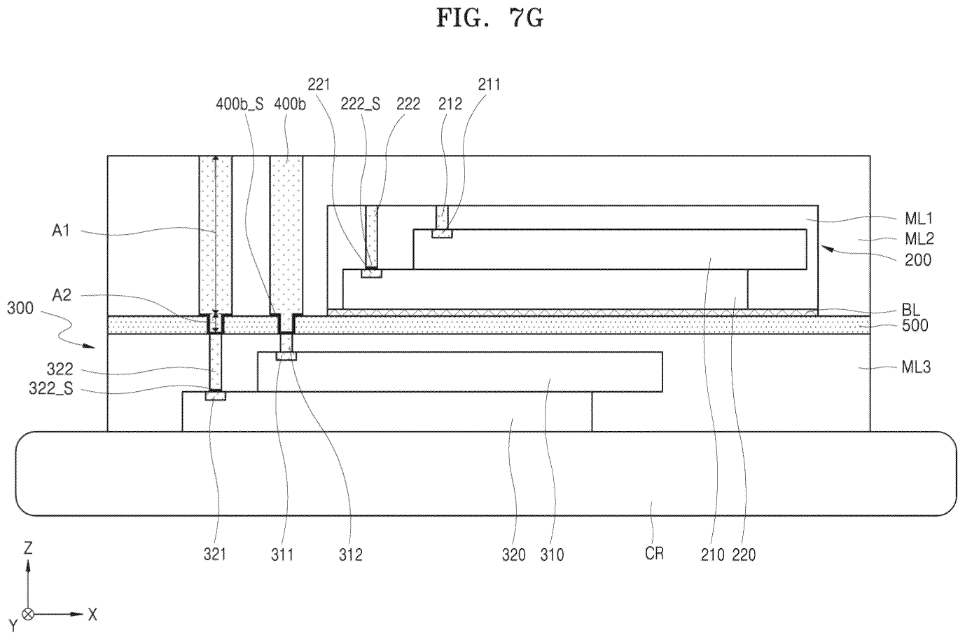

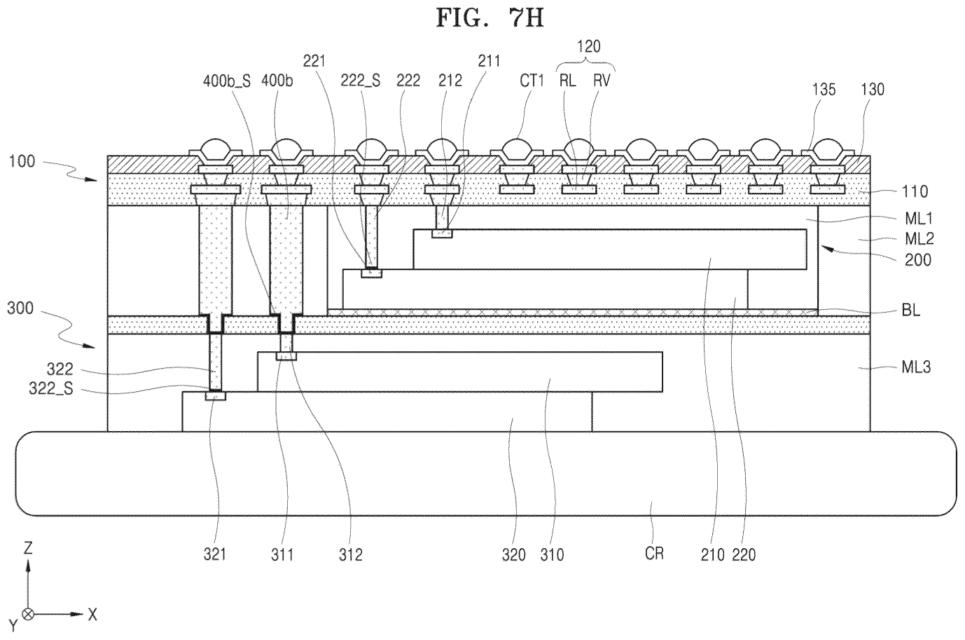

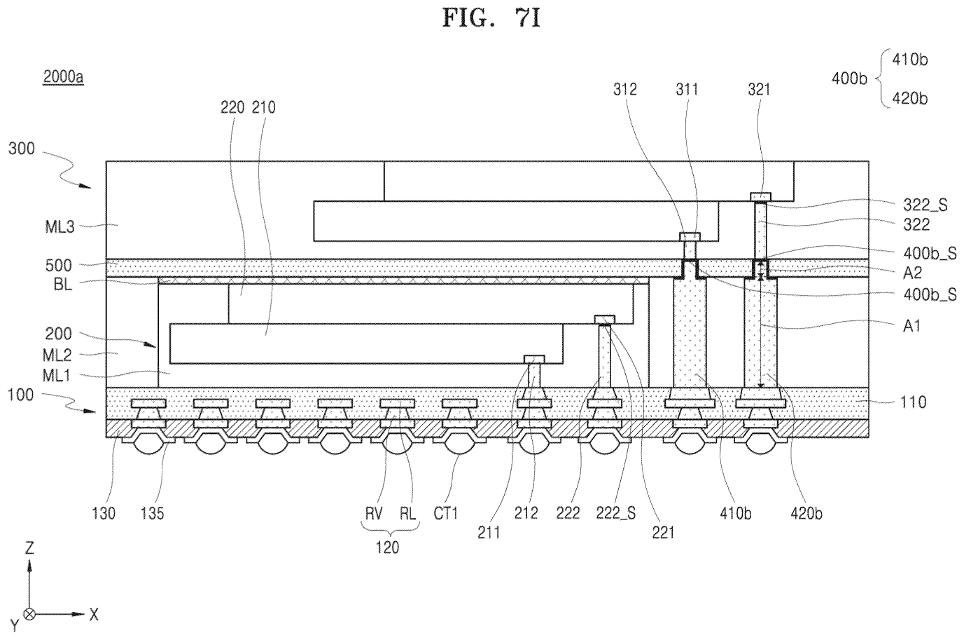

FIGS. 7A to 7I are cross-sectional views illustrating, according to a process sequence, a method of manufacturing the semiconductor package 2000a, according to one or more embodiments.

Referring to FIG. 7A, a second chip structure 300 may be formed on a carrier substrate CR. For example, the process of manufacturing the second chip structure 300 of FIG. 7A may be substantially identical to the process of manufacturing the second chip structure 300 described above with reference to FIGS. 6A to 6F.

Referring to FIGS. 7B and 7C, an intermediate insulating layer 500 and third trenches TR_500 may be formed on the second chip structure 300.

The intermediate insulating layer 500 may be formed to be provided on and cover an upper surface of an upper molding layer ML3 of the second chip structure 300. For example, the intermediate insulating layer 500 may include PID resin. Thereafter, through a photo process, third trenches TR_500 extending from an upper surface of the intermediate insulating layer 500 to a lower surface of the intermediate insulating layer 500 may be formed. One of the third trenches TR_500 may be located above a first upper chip post 312, and another one of the third trenches TR_500 may be located above a second upper chip post 322. An upper surface of the first upper chip post 312 and an upper surface of the second upper chip post 322 may be exposed to the outside by the third trenches TR_500.

Thereafter, a first seed layer 400b_S may be formed on an upper surface of the result of FIG. 7B. For example, the first seed layer 400b_S may be conformally formed on the upper surface of the intermediate insulating layer 500 and inside the third trenches TR_500. For example, the first seed layer 400b_S may be in contact with the first upper chip post 312 and the second upper chip post 322. In addition, when the internal width of each of the third trenches TR_500 is greater than the horizontal width of each of the first upper chip post 312 and the second upper chip post 322, the first seed layer 400b_S may be in contact with a portion of the upper molding layer ML3.

Referring to FIGS. 7D and 7E, a plurality of conductive posts 400b may be formed on the intermediate insulating layer 500.

A second photoresist PR2 may be formed on the result of FIG. 7C, and then, through a photo process, second trenches TR2 extending from an upper surface of the second photoresist PR2 to a lower surface of the second photoresist PR2 may be formed.

For example, the second trenches TR2 may communicate with the third trenches TR_500. The second trenches TR2 may be formed above the third trenches TR_500. Portions of the first seed layer 400b_S, which are located inside the second trenches TR2, may be exposed to the outside by the second trenches TR2 and the third trenches TR_500.

In one or more embodiments, the internal width of each of the third trenches TR_500 and the internal width of each of the second trenches TR2 may be independent of each other. In FIG. 7E, the internal width of each of the third trenches TR_500 may be greater than the internal width of each of the second trenches TR2, but the magnitude relationship between the internal width of each of the third trenches TR_500 and the internal width of each of the second trenches TR2 is not limited thereto. The internal width of each of the third trenches TR_500 may be less than or equal to the internal width of each of the second trenches TR2 in the horizontal direction.

Thereafter, through an electrolytic plating process, the second trenches TR2 and the third trenches TR_500 may be filled with a conductive material to thereby form a plurality of conductive posts 400b. For example, in an electrolytic plating process, the second trenches TR2 and the third trenches TR_500 may be filled with a conductive material by using the first seed layer 400b_S as a starting point.

The second trenches TR2 and the third trenches TR_500 may be located above at least one of the first upper chip post 312 and the second upper chip post 322. The plurality of conductive posts 400b may be formed in the second trenches TR2 and the third trenches TR_500. Portions of the plurality of conductive posts 400b may be connected to the first upper chip post 312, and other portions of the plurality of conductive posts 400b may be connected to the second upper chip post 322.

Each of the plurality of conductive posts 400b may include a first portion A1 and a second portion A2. For example, the first portion A1 of each of the plurality of conductive posts 400b may be a portion formed in one of the second trenches TR2, the second portion A2 of each of the plurality of conductive posts 400b may be a portion formed in one of the third trenches TR_500. Accordingly, the width of each of the plurality of conductive posts 400b in the first portion A1 of each of the plurality of conductive posts 400b may correspond to the internal width of each of the second trenches TR2, and the width of each of the plurality of conductive posts 400b in the second portion A2 of each of the plurality of conductive posts 400b may correspond to the internal width of each of the third trenches TR_500 in the horizontal direction.

Thereafter, the second photoresist PR2 may be removed, and a portion of the first seed layer 400b_S may be removed. For example, portions of the first seed layer 400b_S which are exposed to the outside by removing the second photoresist PR2, that is, portions of the first seed layer 400b_S which are located below the second photoresist PR2, may be removed. For example, portions of the first seed layer 400b_S which are located below the plurality of conductive posts 400 may not be removed. That is, the first seed layer 400b_S may be located between each of the plurality of conductive posts 400b and the intermediate insulating layer 500 and on a lower surface of each of the plurality of conductive posts 400b.

Referring to FIG. 7F, a first chip structure 200 may be attached onto the intermediate insulating layer 500. The first chip structure 200, which is pre-manufactured on a separate carrier substrate, may be attached onto the intermediate insulating layer 500. The first chip structure 200 may be attached onto the intermediate insulating layer 500 through a bonding layer BL. For example, the bonding layer BL may be located on the first chip structure 200 and the intermediate insulating layer 500.

The first chip structure 200 may be spaced apart from the plurality of conductive posts 400b in the horizontal direction. For example, the first chip structure 200 may not overlap an I/O pad 311 of a first upper semiconductor chip 310 and an I/O pad 321 of a second upper semiconductor chip 320 in the vertical direction.

The first chip structure 200 may include a first lower semiconductor chip 210, a first lower chip post 212, a second lower semiconductor chip 220, a second lower chip post 222, and a first lower molding layer ML1. For example, the second lower semiconductor chip 220 and the second lower chip post 222 of the first chip structure 200 may respectively correspond to the second upper semiconductor chip 320 and the second upper chip post 322 of the second chip structure 300. The first lower semiconductor chip 210 and the first lower chip post 212 of the first chip structure 200 may respectively correspond to the first upper semiconductor chip 310 and the first upper chip post 312 of the second chip structure 300.

The first chip structure 200 may be manufactured through a manufacturing process that is substantially identical to the manufacturing process of the second chip structure 300 described above with reference to FIGS. 6A to 6F. For example, the first chip structure 200 may be manufactured by dicing the second chip structure 300 of FIG. 7A. For example, the size of the first lower molding layer ML1 of the first chip structure 200 may be less than the size of the upper molding layer ML3.

Referring to FIG. 7G, a second lower molding layer ML2 may be formed to be provided on and cover the plurality of conductive posts 400b and the first chip structure 200. For example, the first chip structure 200 may be buried inside the second lower molding layer ML2.

An interface may be present between the first lower molding layer ML1 of the first chip structure 200 and the second lower molding layer ML2. Because the first chip structure 200 manufactured on a separate carrier substrate is attached onto the second chip structure 300 and then the second lower molding layer ML2 is formed to be provided on and cover the first chip structure 200, there may be a difference in curing time between the first lower molding layer ML1 of the first chip structure 200 and the second lower molding layer ML2. Due to the difference in curing time, even when the first lower molding layer ML1 and the second lower molding layer ML2 include identical constituent materials, an interface may be present between the first lower molding layer ML1 and the second lower molding layer ML2.

Thereafter, the second lower molding layer ML2 may be removed until an upper surface of the first chip structure 200 is exposed to the outside. For example, the first lower chip post 212 of the first chip structure 200, the second lower chip post 222 of the first chip structure 200, and the plurality of conductive posts 400 may be exposed to the outside. For example, an upper surface of the second lower molding layer ML2, an upper surface of each of the plurality of conductive posts 400, an upper surface of the first lower molding layer ML1 of the first chip structure 200, an upper surface of the first lower chip post 212 of the first chip structure 200, and an upper surface of the second lower chip post 222 of the first chip structure 200 may be coplanar with each other.

Referring to FIG. 7H, a redistribution structure 100 may be formed on the first chip structure 200 and the second lower molding layer ML2. The redistribution structure 100 may include redistribution patterns 120 and a redistribution insulating layer 110 surrounding the redistribution patterns 120. Thereafter, a passivation layer 130 and lower metal layers 135 may be formed on the redistribution structure 100. Thereafter, external connection terminals CT1 may be attached onto the lower metal layers 135.

For example, the redistribution structure 100 may be formed such that redistribution vias RV of the redistribution patterns 120 of the redistribution structure 100 are in contact with the plurality of conductive posts 400b, the first lower chip post 212 of first chip structure 200, and the second lower chip post 222 of the first chip structure 200. For example, each of the redistribution vias RV may be formed to have a width in the horizontal direction that decreases downward in the vertical direction (Z direction). For example, the width of each of the redistribution via RV in the horizontal direction may decrease in the horizontal direction toward the upper surface of the first chip structure 200. Thereafter, the upper molding layer ML3 and the second upper semiconductor chip 320 may be separated from the carrier substrate CR to thereby manufacture a semiconductor package 2000a.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a redistribution structure;
a first chip structure on the redistribution structure and comprising a first lower semiconductor chip, a second lower semiconductor chip on the first lower semiconductor chip in a vertical direction and shifted with respect to the first lower semiconductor chip in a horizontal direction, and a first lower molding layer on the first lower semiconductor chip and the second lower semiconductor chip;
a second lower molding layer on the redistribution structure and side surfaces of the first chip structure;
a plurality of conductive posts spaced apart from the first chip structure, on the redistribution structure, penetrating the second lower molding layer, a plurality of conductive posts comprising a first conductive post and a second conductive post; and
a second chip structure on the first chip structure, the second lower molding layer, and the plurality of conductive posts, the second chip structure comprising a first upper semiconductor chip, a first upper chip post extending from the first upper semiconductor chip to the first conductive post, a second upper semiconductor chip on the first upper semiconductor chip in the vertical direction and shifted with respect to the first upper semiconductor chip in the horizontal direction, a second upper chip post extending from the second upper semiconductor chip to the second conductive post, and an upper molding layer on the first upper semiconductor chip, the first upper chip post, the second upper semiconductor chip, and the second upper chip post,
wherein a width of the first upper chip post included in the second chip structure is less than a width of the first conductive post in the horizontal direction,
wherein a width of the second upper chip post included in the second chip structure is less than a width of the second conductive post in the horizontal direction, and
wherein a side surface of the upper molding layer included in the second chip structure is coplanar with a side surface of the second lower molding layer.

2. The semiconductor package of claim 1, wherein a distance between the second conductive post among the plurality of conductive posts and the first chip structure is greater than a distance between the first conductive post among the plurality of conductive posts and the first chip structure in the horizontal direction.

3. The semiconductor package of claim 1, wherein the first chip structure further comprises a bonding layer on an upper surface of the first chip structure, and
wherein the bonding layer is between the first chip structure and the upper molding layer included in the second chip structure.

4. The semiconductor package of claim 3, wherein the second lower molding layer on side surfaces of the first lower molding layer and side surfaces of the bonding layer, and
wherein an upper surface of the second lower molding layer is coplanar with an upper surface of the bonding layer.

5. The semiconductor package of claim 1, wherein a material of the first lower molding layer included in the first chip structure is the same as a material of the second lower molding layer, and
wherein an interface is between the first lower molding layer included in the first chip structure and the second lower molding layer.

6. The semiconductor package of claim 1, wherein the first chip structure further comprises a first lower chip post and a second lower chip post,
wherein the first lower chip post penetrates the first lower molding layer and extends in the vertical direction from a lower surface of the first lower semiconductor chip to an upper surface of the redistribution structure, and
wherein the second lower chip post penetrates the first lower molding layer and extends in the vertical direction from a lower surface of the second lower semiconductor chip to the upper surface of the redistribution structure.

7. The semiconductor package of claim 6, wherein a height of the second lower chip post of the first chip structure is less than a height of each post among the plurality of conductive posts in the vertical direction.

8. The semiconductor package of claim 6, wherein a width of the first lower chip post of the first chip structure is less than a width of each post among the plurality of conductive posts in the horizontal direction, and
wherein a width of the second lower chip post of the first chip structure is less than the width of each post among the plurality of conductive posts in the horizontal direction.

9. The semiconductor package of claim 6, wherein the first lower semiconductor chip is spaced apart from the redistribution structure in the vertical direction, the first lower molding layer being between the first lower semiconductor chip and the redistribution structure, and
wherein the first upper semiconductor chip is spaced apart from the first chip structure and the second lower molding layer in the vertical direction, the upper molding layer being between the first upper semiconductor chip and the second lower molding layer.

10. The semiconductor package of claim 1, wherein the redistribution structure comprises a redistribution line and a redistribution via extending in the vertical direction from the redistribution line, and
wherein a width of the redistribution via in the horizontal direction increases toward a lower surface of the first chip structure in the vertical direction.

11. The semiconductor package of claim 1, wherein an area of the second upper semiconductor chip of the second chip structure that overlaps with the first chip structure in the vertical direction is less than an area of the first upper semiconductor chip of the second chip structure that overlaps with the first chip structure in the vertical direction.

12. A semiconductor package comprising:
a redistribution structure;
a first chip structure on the redistribution structure and comprising a first lower semiconductor chip, a second lower semiconductor chip on the first lower semiconductor chip in a vertical direction and shifted with respect to the first lower semiconductor chip in a horizontal direction, and a first lower molding layer on the first lower semiconductor chip and the second lower semiconductor chip;
a second lower molding layer on the redistribution structure and side surfaces of the first chip structure;
an intermediate insulating layer on the first chip structure and the second lower molding layer;
a plurality of conductive posts spaced apart from the first chip structure, on the redistribution structure, penetrating the second lower molding layer and the intermediate insulating layer, the plurality of conductive posts comprising a first conductive post and a second conductive post; and
a second chip structure on the intermediate insulating layer and the plurality of conductive posts, the second chip structure comprising a first upper semiconductor chip, a first upper chip post extending from the first upper semiconductor chip to the first conductive post, a second upper semiconductor chip on the first upper semiconductor chip in the vertical direction and shifted with respect to the first upper semiconductor chip in the horizontal direction, a second upper chip post extending from the second upper semiconductor chip to the second conductive post, and an upper molding layer on the first upper semiconductor chip, the first upper chip post, the second upper semiconductor chip, and the second upper chip post,
wherein a width of the first upper chip post of the second chip structure is less than a width of the first conductive post in a horizontal direction,
wherein a width of the second upper chip post of the second chip structure is less than a width of the second conductive post in the horizontal direction, and
wherein a side surface of the upper molding layer of the second chip structure, a side surface of the second lower molding layer, and a side surface of the intermediate insulating layer are coplanar with each other.

13. The semiconductor package of claim 12, wherein each post among the plurality of conductive posts comprises a first portion penetrating the second lower molding layer, and a second portion penetrating the intermediate insulating layer, and
wherein a width of the first portion of each post among the plurality of conductive posts is different from a width of the second portion of each post among the plurality of conductive posts.

14. The semiconductor package of claim 12, wherein each post among the plurality of conductive posts comprises a first seed layer, and
wherein the first seed layer of each post among the plurality of conductive posts is on portions of side surfaces of each post among the plurality of conductive posts that are surrounded by the intermediate insulating layer, and on an upper surface of each post among the plurality of conductive posts.

15. The semiconductor package of claim 12, wherein the first chip structure further comprises a first lower chip post and a second lower chip post,
wherein the first lower chip post penetrates the first lower molding layer and extends in the vertical direction from a lower surface of the first lower semiconductor chip to an upper surface of the redistribution structure, and
wherein the second lower chip post penetrates the first lower molding layer and extends in the vertical direction from a lower surface of the second lower semiconductor chip to the upper surface of the redistribution structure.

16. The semiconductor package of claim 15, wherein the first chip structure further comprises a lower seed layer between the second lower semiconductor chip and the second lower chip post.

17. The semiconductor package of claim 12, wherein the second chip structure further comprises an upper seed layer between the second upper semiconductor chip and the second upper chip post.

18. A semiconductor package comprising:
a redistribution structure comprising a redistribution pattern and a redistribution insulating layer on the redistribution pattern;
a first chip structure on the redistribution structure and comprising a first lower semiconductor chip, a first lower chip post extending downward from the first lower semiconductor chip to the redistribution structure, a second lower semiconductor chip on the first lower semiconductor chip in a vertical direction and shifted with respect to the first lower semiconductor chip in a horizontal direction, a second lower chip post extending downward from the second lower semiconductor chip to the redistribution structure, and a first lower molding layer on the first lower semiconductor chip, the first lower chip post, the second lower semiconductor chip, and the second lower chip post;
a bonding layer on an upper surface of the first chip structure;
a second lower molding layer on the redistribution structure, side surfaces of the first chip structure, and side surfaces of the bonding layer;
a plurality of conductive posts spaced apart from the first chip structure in a horizontal direction, on the redistribution structure, and penetrating the second lower molding layer, the plurality of conductive posts comprising a first conductive post and a second conductive post; and
a second chip structure on the first chip structure, the second lower molding layer, and the plurality of conductive posts and comprising a first upper semiconductor chip, a first upper chip post extending from the first upper semiconductor chip to the first conductive post, a second upper semiconductor chip on the first upper semiconductor chip in the vertical direction and shifted with respect to the first upper semiconductor chip in the horizontal direction, a second upper chip post extending from the second upper semiconductor chip to the second conductive post, and an upper molding layer on the first upper semiconductor chip, the first upper chip post, the second upper semiconductor chip, and the second upper chip post,
wherein an interface is between the first lower molding layer of the first chip structure and the second lower molding layer,
wherein a width of each post among the plurality of conductive posts is greater than a width of the first lower chip post, a width of the second lower chip post, a width of the first upper chip post, and a width of the second upper chip post in the horizontal direction, and
wherein a side surface of the upper molding layer of the second chip structure is coplanar with a side surface of the second lower molding layer.

19. The semiconductor package of claim 18, wherein the first upper semiconductor chip of the second chip structure comprises an input/output (I/O) pad which is on a lower surface of the first upper semiconductor chip, is in contact with the first upper chip post, and does not overlap the first chip structure in the vertical direction, and
wherein the second upper semiconductor chip of the second chip structure comprises an I/O pad which is on a lower surface of the second upper semiconductor chip, is in contact with the second upper chip post, and does not overlap the first upper semiconductor chip and the first chip structure in the vertical direction.

20. The semiconductor package of claim 18, further comprising an intermediate insulating layer between the bonding layer and the upper molding layer of the second chip structure and between the second lower molding layer and the upper molding layer of the second chip structure,
wherein the plurality of conductive posts penetrate the intermediate insulating layer and the second lower molding layer, and
wherein the semiconductor package further comprises a first seed layer on portions of side surfaces of each post among the plurality of conductive posts, the portions penetrating the second lower molding layer, and on an upper surface of each post among the plurality of conductive posts.
